(19) United States
(12) Patent Application Publication
(10) Pub. No.: US 2026/0293377 A1
(43) Pub. Date: Sep. 24, 2026

(54) SEMICONDUCTOR LIGHT-EMITTING ELEMENT, AND DISPLAY DEVICE

(71) Applicant: LG ELECTRONICS INC., Seoul (KR)

(72) Inventors: Jinhyuk JUNG, Seoul (KR); Byoungkwon CHO, Seoul (KR); Youngsung YANG, Seoul (KR); Wonseok CHOI, Seoul (KR)

(73) Assignee: LG ELECTRONICS INC., Seoul (KR)

(21) Appl. No.: 19/133,574

(22) PCT Filed: Nov. 28, 2022
(86) PCT No.: PCT/KR2022/018912

§ 371 Date: May 28, 2025

(51) Int. Cl. H10H 20/82; H10H 20/01; H10H 20/831; H10H 20/832; H10H 20/84; H10H 29/49

(52) U.S. Cl. CPC H10H 20/82; H10H 20/017; H10H 20/032; H10H 20/831; H10H 20/832; H10H 29/49; H10H 20/84

(57) ABSTRACT

A semiconductor light-emitting element may include a light-emitting layer, a passivation layer surrounding the light-emitting layer, a first electrode comprising a first non-uniform region under the light-emitting layer, and a second non-uniform region under the first non-uniform region, and a second electrode on the light-emitting layer. The first non-uniform region may include a plurality of first negative patterns and a plurality of first protrusions in the plurality of first negative patterns. The second non-uniform region may include a plurality of second negative patterns and a plurality of second protrusions in the plurality of second negative patterns. The plurality of second negative patterns may have shapes corresponding to shapes of the plurality of first negative patterns, respectively. The plurality of second protrusions may have shapes corresponding to shapes of the plurality of first protrusions.

### TECHNICAL FIELD

The embodiment relates to a semiconductor light-emitting element and a display device.

### BACKGROUND ART

A large-area display includes a liquid crystal display (LCD), an OLED display, and a micro-LED display.

The micro-LED display is a display that uses micro-LEDs, which are semiconductor light-emitting elements with a diameter or cross-sectional area of 100 μm or less, as display elements.

Since the micro-LED display uses the micro-LEDs, which are the semiconductor light-emitting elements, as the display elements, it has excellent performance in many characteristics such as contrast ratio, response speed, color reproducibility, viewing angle, brightness, resolution, lifespan, light emission efficiency, or luminance.

In particular, the micro-LED display has the advantage of being able to freely adjust the size or resolution by separating and combining the screens in a modular manner, and the advantage of being able to implement a flexible display.

However, since large micro-LED displays require millions or more micro-LEDs, there is a technical problem that makes it difficult to quickly and accurately transfer micro-LEDs to a display panel.

Recently developed transfer technologies include the pick and place process, the laser lift-off method, and the self-assembly method.

Among these, the self-assembly method is a method in which the semiconductor light-emitting elements find their assembly positions within a fluid, which is advantageous for implementing a large-screen display device.

However, research on the technology for manufacturing displays through self-assembly of micro-LEDs is still insufficient.

In particular, in the case of rapidly transferring millions or more semiconductor light-emitting elements to a large display in the conventional technology, the transfer speed can be improved, but the transfer error rate may increase, which causes a technical problem in that the transfer yield decreases.

In the related technology, a self-assembly transfer process using dielectrophoresis (DEP) is being attempted, but there is a problem that the self-assembly rate is low due to the non-uniformity of the DEP force.

On the other hand, the size (or diameter) of the micro-LED is very small, so that an area where an electrode provided on the lower side comes into contact with a semiconductor layer is very small. In other words, a contact area between the semiconductor layer and the electrode is very small, which leads to an increase in surface resistance and a problem of reduced electrical characteristics.

In addition, since a lower surface of the semiconductor layer of the micro-LED has a straight plane and the electrode is provided on the straight plane, there is a problem that the light that has traveled downward toward the electrode is absorbed by the electrode, resulting in a decrease in the light emission efficiency.

In addition, in the self-assembly method, the semiconductor light-emitting element moving on the backplane substrate is assembled at a specific site on the backplane substrate using the DEP force. In order to better assemble the semiconductor light-emitting element, the DEP force must be large. In particular, in the case of ultra-small LEDs such as micro-LEDs, the DEP force must be increased to improve the assembly rate of micro-LEDs, but there is a problem that power consumption increases.

In addition, the micro-LED is fixed by the DEP force while it is assembled on the backplane substrate and the electrical connection is formed by the post-process. However, there is a limit to fixing the micro-LED on the backplane substrate by the DEP force, and there is a problem that the micro-LED is detached from the backplane substrate when various processes are performed for the electrical connection.

In addition, when the micro-LED is circular, it is not fixed and rotates frequently even when assembled on the backplane substrate. Therefore, since the micro-LED is not fixed in the correct position, electrical connection defect due to misalignment, etc. occurs, causing a problem of lighting defect.

### DISCLOSURE

### Technical Problem

An object of the embodiment is to solve the foregoing and other problems.

Another object of the embodiment is to provide a semiconductor light-emitting element capable of improving electrical characteristics.

In addition, another object of the embodiment is to provide a semiconductor light-emitting element capable of improving light emission efficiency.

In addition, another object of the embodiment is to provide a semiconductor light-emitting element capable of improving an assembly rate and reducing power consumption for self-assembly.

In addition, another object according to the embodiment is to provide a display device capable of enhancing the fixation of a semiconductor light-emitting element.

In addition, another object according to the embodiment is to provide a display device equipped with a semiconductor light-emitting element capable of correct-position assembly.

The technical problems of the embodiments are not limited to those described in this item and comprise those that may be understood through the description of the invention.

### Technical Solution

In order to achieve the above or other objects, according to one aspect of the embodiment, a semiconductor light-emitting element, comprising: a light-emitting layer; a passivation layer surrounding the light-emitting layer; a first non-uniform region under the light-emitting layer; a first electrode comprising a second non-uniform region under the first non-uniform region; and a second electrode on the light-emitting layer; wherein the first non-uniform region comprises a plurality of first negative patterns and a plurality of first protrusions on the plurality of first negative patterns, wherein the second non-uniform region comprises a plurality of second negative patterns and a plurality of second protrusions on the plurality of second negative patterns, wherein the plurality of second negative patterns have shapes corresponding to shapes of the plurality of first negative patterns, respectively, and wherein the plurality of second protrusions have shapes corresponding to shapes of the plurality of first protrusions, respectively.

The first negative pattern and the second negative pattern have ring shapes around the first protrusion and the second protrusion, respectively.

The light-emitting layer comprises a first conductivity type semiconductor layer; an active layer on the first conductivity type semiconductor layer; and a second conductivity type semiconductor layer on the active layer; and the first conductivity type semiconductor layer may have a thickness of 70% or more of the total thickness of the light-emitting layer.

The height of the first protrusion may be 20% to 70% of the thickness of the first conductivity type semiconductor layer.

The first electrode may comprise a plurality of metal layers comprising at least an ohmic contact layer and a magnetic layer, and each of the plurality of metal layers may have a thickness of 50 nm or less.

The semiconductor light-emitting element may comprise a first uniform region under the light-emitting layer, and the first electrode may comprise a second uniform region having a shape corresponding to the shape of the first uniform region.

The second non-uniform region may comprise a second-first non-uniform region under the first emission region of the light-emitting layer; and a second-second non-uniform region under the second emission region of the light-emitting layer; and the second uniform region may be positioned between the second-first non-uniform region and the second-second non-uniform region.

The second uniform region may comprise a second-first uniform region under the first emission region of the light-emitting layer; and a second-second uniform region under the second emission region of the light-emitting layer; and the second non-uniform region may be positioned between the second-first uniform region and the second-second uniform region.

The first uniform region and the first non-uniform region may be parts of the first conductivity type semiconductor layer.

The first uniform region may have a first recess formed on a lower surface of the first conductivity type semiconductor layer, and the second uniform region may have a second recess corresponding to the first recess.

A surface of the first uniform region may be positioned on a same horizontal line as a bottom of the first negative pattern.

According to another aspect of the embodiment, a display device comprises: a backplane substrate; the semiconductor light-emitting element on the backplane substrate; a fixing member between the backplane substrate and the semiconductor light-emitting element; a connecting electrode on a lateral part of the semiconductor light-emitting element; and an electrode wiring on the upper side of the semiconductor light-emitting element, wherein the connecting electrode may be connected to at least one of the first assembly wiring or the second assembly wiring of the backplane substrate.

The fixing member may be disposed in the second recess.

The fixing member may be disposed on the plurality of second negative patterns of the first electrode.

### Advantageous Effects

As illustrated in FIG. 7, FIG. 26, and FIG. 32, a second non-uniform region 156 may be included in a first electrode 154 provided on a lower side of a semiconductor light-emitting element 150A, 150B, and 150C. The second non-uniform region 156 may comprise a plurality of second negative patterns 156a and a plurality of second protrusions 156b. At this time, the plurality of second protrusions 156b may be disposed on the plurality of second negative patterns 156a.

According to the embodiment, since a first electrode 154 comprises the second non-uniform region 156 comprising the plurality of second negative patterns 156a and the plurality of second protrusions 156b, a contact area between the first electrode 154 and a light-emitting layer 150a can be significantly increased, so that the electrical characteristics can be improved. In addition, an area of the magnetic layer included in the first electrode 154 during self-assembly may be increased, so that the assembly rate can be improved, and since the DEP force for self-assembly is increased, a low voltage may be applied, so that power consumption can be reduced.

According to an embodiment, since the first electrode 154 comprises a second non-uniform region 156 comprising a plurality of second negative patterns 156a and a plurality of second protrusions 156b, light generated from the light-emitting layer 150a may be diffusely reflected by the second non-uniform region 156 comprising a plurality of second negative patterns 156a and a plurality of second protrusions 156b, so that the light emission efficiency can be improved.

Meanwhile, as illustrated in FIG. 26 and FIG. 32, a second uniform region 156′ having a second recess 159b may be included in the first electrode 154 provided on the lower side of the semiconductor light-emitting element 150B and 150C. Accordingly, as illustrated in FIG. 41 and FIG. 44, the semiconductor light-emitting element 150B and 150C may be assembled and fixed by a fixing member 390. At this time, the fixing member 390 may be disposed in the second recess 159b of the second uniform region 156′, so that a contact area between the fixing member 390 and the semiconductor light-emitting element 150B and 150C can be maximized. Accordingly, since the semiconductor light-emitting element 150B and 150C are more firmly fixed to a first insulating layer 330 by the fixing member 390, a fixing property of the semiconductor light-emitting element 150B and 150C can be further strengthened.

Meanwhile, as illustrated in FIGS. 28 and 29, even when a circular semiconductor light-emitting element 150B is assembled into an assembly hole 340H of a backplane substrate 300A in a state of being rotated by a predetermined angle from its correct position, a second-first non-uniform region 156-1 and a second-second non-uniform region 156-2, which are positioned on both sides of the second uniform region 156′ in the first electrode 154, may be self-aligned to overlap with the first assembly wiring 321 and the second assembly wiring 322, respectively, so that the semiconductor light-emitting element 150B may be assembled in its correct position. For example, the second-first non-uniform region 156-1 and the second-second non-uniform region 156-2, respectively, positioned on both sides of the second uniform region 156′, may be aligned with the first assembly wiring 321 and the second assembly wiring 322 to set the semiconductor light-emitting element 150B to its correct position. In this instance, when the semiconductor light-emitting element 150B is not assembled in the correct position in the assembly hole 340H, a separate alignment process for assembling it in the correct position does not need to be performed, and a problem caused by not being aligned in the correct position, i.e., electrical connection defect due to misalignment, can be prevented.

Additional scope of applicability of the embodiments will become apparent from the detailed description that follows. However, since various changes and modifications within the idea and scope of the embodiments may be clearly understood by those skilled in the art, the detailed description and specific embodiments, such as preferred embodiments, should be understood as being given by way of example only.

### DESCRIPTION OF DRAWINGS

FIG. 1 illustrates a living room of a house in which a display device according to the embodiment is disposed.

FIG. 2 is a block diagram schematically showing a display device according to the embodiment.

FIG. 3 is a circuit diagram showing an example of a pixel of FIG. 2.

FIG. 4 is an enlarged view of the first panel region in the display device of FIG. 1.

FIG. 5 is an enlarged view of the region A2 of FIG. 4.

FIG. 6 is a drawing illustrating an example of assembling a light-emitting element according to an embodiment on a substrate by a self-assembly method.

FIG. 7 is a cross-sectional view illustrating a semiconductor light-emitting element according to a first embodiment.

FIG. 8 is a bottom view of a semiconductor light-emitting element according to the first embodiment with the first electrode removed.

FIGS. 9 to 17 show a method for manufacturing a semiconductor light-emitting element according to the first embodiment.

FIG. 18 is a cross-sectional view illustrating a display device according to the first embodiment.

FIG. 19 is a cross-sectional view illustrating a backplane substrate according to the embodiment.

FIGS. 20A to 25 show a method for manufacturing a display device according to the first embodiment.

FIG. 26 is a cross-sectional view illustrating a semiconductor light-emitting element according to a second embodiment.

FIG. 27 is a bottom view of a semiconductor light-emitting element according to the second embodiment with the first electrode removed.

FIGS. 28 and 29 show a self-aligned semiconductor light-emitting element during self-assembly.

FIG. 30 shows a DEP force reflecting the shape of the lower side of the semiconductor light-emitting element during self-assembly.

FIGS. 31 to 40 show a method for manufacturing a semiconductor light-emitting element according to the second embodiment.

FIG. 41 is a cross-sectional view illustrating a display device according to the second embodiment.

FIG. 42 is a cross-sectional view illustrating a semiconductor light-emitting element according to a third embodiment.

FIG. 43 is a bottom view of a semiconductor light-emitting element according to the third embodiment with the first electrode removed.

FIG. 44 is a cross-sectional view illustrating a display device according to the third embodiment.

The sizes, shapes, dimensions, etc. of elements illustrated in the drawings may differ from actual ones. In addition, even if the same elements are illustrated in different sizes, shapes, dimensions, etc. between the drawings, this is only an example on the drawing, and the same elements have the same sizes, shapes, dimensions, etc. between the drawings.

### MODE FOR INVENTION

Hereinafter, the embodiment disclosed in this specification will be described in detail with reference to the accompanying drawings, but the same or similar elements are given the same reference numerals regardless of reference numerals, and redundant descriptions thereof will be omitted. The suffixes ‘module’ and ‘unit’ for the elements used in the following descriptions are given or used interchangeably in consideration of ease of writing the specification, and do not themselves have a meaning or role that is distinct from each other. In addition, the accompanying drawings are for easy understanding of the embodiment disclosed in this specification, and the technical idea disclosed in this specification is not limited by the accompanying drawings. Also, when an element such as a layer, region or substrate is referred to as being ‘on’ another element, this means that there may be directly on the other element or be other intermediate elements therebetween.

The display device described in this specification may comprise a TV, a signage, a mobile terminal such as a mobile phone or a smart phone, a computer display such as a laptop or a desktop, a head-up display (HUD) for an automobile, a backlight unit for display, a display for an extended reality (XR) such as AR, VR, and a mixed reality (MR), a light source, etc. However, the configuration according to the embodiment described in this specification may be equally applied to a device capable of displaying, even if it is a new product type developed in the future.

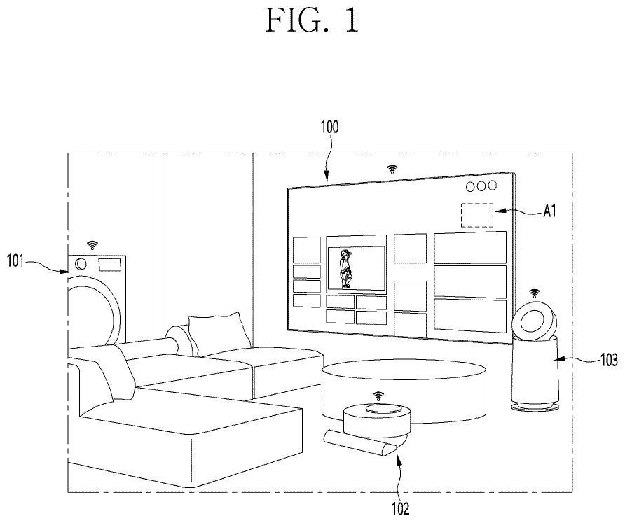

FIG. 1 illustrates a living room of a house in which a display device according to an embodiment is disposed.

Referring to FIG. 1, the display device 100 according to the embodiment may display the status of various electronic products such as a washing machine 101, a robot vacuum cleaner 102, and an air purifier 103, and may communicate with each electronic product based on IoT and control each electronic product based on the user's setting data.

The display device 100 according to the embodiment may comprise a flexible display manufactured on a thin and flexible substrate. The flexible display may be bent or rolled like paper while maintaining the characteristics of a conventional flat panel display.

In the flexible display, visual information may be implemented by independently controlling the light emission of unit pixels disposed in a matrix form. A unit pixel means a minimum unit for implementing one color. The unit pixel of the flexible display may be implemented by a light-emitting element. In the embodiment, the light-emitting element may be a micro-LED or a nano-LED, but is not limited thereto.

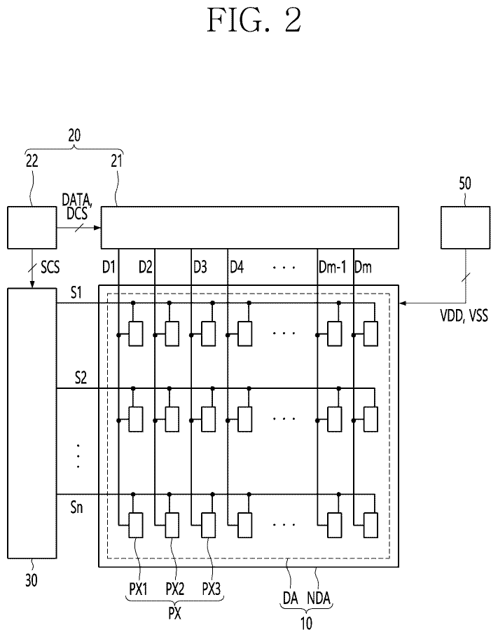

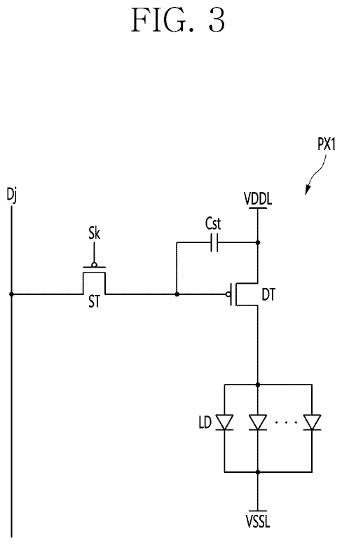

FIG. 2 is a block diagram schematically showing a display device according to an embodiment, and FIG. 3 is a circuit diagram showing an example of a pixel of FIG. 2.

Referring to FIG. 2 and FIG. 3, a display device according to an embodiment may comprise a display panel 10, a driving circuit 20, a scan driving unit 30, and a power supply circuit 50.

The display device 100 of the embodiment may drive a light-emitting element in an active matrix (AM) manner or a passive matrix (PM) manner.

The driving circuit 20 may comprise a data driving unit 21 and a timing control unit 22.

The display panel 10 may be formed in a rectangular shape, but is not limited thereto. That is, the display panel 10 may be formed in a circular or elliptical shape. At least one side of the display panel 10 may be formed to be bent at a predetermined curvature.

The display panel may comprise a display region DA. The display region DA is a region where pixels PX are formed to display an image. The display panel may comprise a non-display region NDA. The non-display region NDA may be a region excluding the display region DA.

As an example, the display region DA and the non-display region NDA may be defined on the same surface. For example, the non-display region NDA may surround the display region DA on the same surface together with the display region DA, but is not limited thereto.

As another example, although not illustrated in the drawing, the display region DA and the non-display region NDA may be defined on different surfaces. For example, the display region DA may be defined on the upper surface of the substrate, and the non-display region NDA may be defined on the lower surface of the substrate. For example, the non-display region NDA may be defined on the overall region or a part of the lower surface of the substrate.

Meanwhile, although the drawing illustrates that the display region DA and the non-display region NDA are separated, the display region DA and the non-display region NDA may not be separated. That is, only the display region DA may exist on the upper surface of the substrate, and the non-display region NDA may not exist. In other words, the overall region of the upper surface of the substrate is the display region DA where the image is displayed, and the bezel area, which is the non-display region NDA, may not exist.

The display panel 10 may comprise data lines (D1 to Dm, where m is an integer greater than or equal to 2), scan lines (S1 to Sn, where n is an integer greater than or equal to 2) intersecting the data lines D1 to Dm, a high-potential voltage line VDDL supplied with a high-potential voltage VDD, a low-potential voltage line VSSL supplied with a low-potential voltage VSS, and pixels PX connected to the data lines D1 to Dm and the scan lines S1 to Sn.

Each of the pixels PX may comprise a first subpixel PX1, a second subpixel PX2, and a third subpixel PX3. The first subpixel PX1 may emit a first color light of a first dominant wavelength, the second subpixel PX2 may emit a second color light of a second dominant wavelength, and the third subpixel PX3 may emit a third color light of a third dominant wavelength. The first color light may be red light, the second color light may be green light, and the third color light may be blue light, but is not limited thereto. In addition, although FIG. 2 illustrates that each of the pixels PX comprises three subpixels, the present invention is not limited thereto. That is, each of the pixels PX may comprise four or more subpixels.

Each of the first subpixel PX1, the second subpixel PX2, and the third subpixel PX3 may be connected to at least one of the data lines DI to Dm, at least one of the scan lines S1 to Sn, and the high-potential voltage line VDDL. The first subpixel PX1 may comprise light-emitting elements LD, a plurality of transistors for supplying current to the light-emitting elements LD, and at least one capacitor Cst, as illustrated in FIG. 3.

Although not illustrated in the drawing, each of the first subpixel PX1, the second subpixel PX2, and the third subpixel PX3 may comprise only one light-emitting element LD and at least one capacitor Cst.

Each of the light-emitting elements LD may be a semiconductor light-emitting diode comprising a first electrode 154, a plurality of conductivity type semiconductor layers, and a second electrode 155. Here, the first electrode 154 may be an anode electrode, and the second electrode 155 may be a cathode electrode, but is not limited thereto.

The light-emitting element LD may be one of a lateral-type light-emitting element, a flip-chip type light-emitting element, and a vertical-type light-emitting element.

The plurality of transistors may comprise a driving transistor DT for supplying current to the light-emitting elements LD, and a scan transistor ST for supplying a data voltage to a gate electrode of the driving transistor DT, as illustrated in FIG. 3. The driving transistor DT may comprise a gate electrode connected to the source electrode of the scan transistor ST, a source electrode connected to the high-potential voltage line VDDL to which the high-potential voltage VDD is applied, and a drain electrode connected to the first electrodes 154 of the light-emitting elements LD. The scan transistor ST may comprise a gate electrode connected to the scan line (Sk, where k is an integer satisfying 1≤k≤n), a source electrode connected to the gate electrode of the driving transistor DT, and a drain electrode connected to the data line (Dj, where j is an integer satisfying 1≤j<m).

A capacitor Cst is formed between the gate electrode and the source electrode of the driving transistor DT. The storage capacitor Cst charges the difference between the gate voltage and the source voltage of the driving transistor DT.

The driving transistor DT and the scan transistor ST may be formed as thin film transistors. In addition, in FIG. 3, the driving transistor DT and the scan transistor ST are described mainly as being formed as a P-type metal oxide semiconductor field effect transistor (MOSFET), but the present invention is not limited thereto. The driving transistor DT and the scan transistor ST may be formed as N-type MOSFETs. In this instance, the positions of the source electrode and the drain electrode of each of the driving transistor DT and the scan transistor ST may be changed.

In addition, in FIG. 3, it is exemplified that each of the first subpixel PX1, the second subpixel PX2, and the third subpixel PX3 comprises 2T1C (2 Transistor—1 capacitor) having one driving transistor DT, one scan transistor ST, and one capacitor Cst, but the present invention is not limited thereto. Each of the first subpixel PX1, the second subpixel PX2, and the third subpixel PX3 may comprise a plurality of scan transistors ST and a plurality of capacitors Cst.

Since the second subpixel PX2 and the third subpixel PX3 may be expressed by substantially the same circuit diagram as the first subpixel PX1, a detailed description thereof will be omitted.

The driving circuit 20 outputs signals and voltages for driving the display panel 10. To this end, the driving circuit 20 may comprise a data driving unit 21 and a timing control unit 22.

The data driving unit 21 receives digital video data DATA and a source control signal DCS from the timing control unit 22. The data driving unit 21 converts digital video data DATA into analog data voltages according to the source control signal DCS and supplies the converted data to data lines D1 to Dm of the display panel 10.

The timing control unit 22 receives digital video data DATA and timing signals from a host system. The host system may be an application processor of a smartphone or tablet PC, a monitor, a system on chip of a TV, etc.

The timing control unit 22 generates control signals for controlling the operation timing of the data driving unit 21 and the scan driving unit 30. The control signals may comprise a source control signal DCS for controlling the operation timing of the data driving unit 21 and a scan control signal SCS for controlling the operation timing of the scan driving unit 30.

The driving circuit 20 may be disposed in a non-display region NDA provided on one side of the display panel 10. The driving circuit 20 may be formed as an integrated circuit (IC) and mounted on the display panel 10 using a chip on glass (COG) method, a chip on plastic (COP) method, or an ultrasonic bonding method, but the present invention is not limited thereto. For example, the driving circuit 20 may be mounted on a circuit board (not illustrated) other than the display panel 10.

The data driving unit 21 may be mounted on the display panel 10 using a chip on glass (COG) method, a chip on plastic (COP) method, or an ultrasonic bonding method, and the timing control unit 22 may be mounted on the circuit board.

The scan driving unit 30 receives a scan control signal SCS from the timing control unit 22. The scan driving unit 30 generates scan signals according to the scan control signal SCS and supplies them to scan lines S1 to Sn of the display panel 10. The scan driving unit 30 may be formed in the non-display region NDA of the display panel 10 comprising a plurality of transistors. Alternatively, the scan driving unit 30 may be formed as an integrated circuit, in which case it may be mounted on a gate flexible film attached to another side of the display panel 10.

The power supply circuit 50 may generate voltages required for driving the display panel 10 from a main power applied from a system board and supply them to the display panel 10. For example, the power supply circuit 50 may generate a high-potential voltage VDD and a low-potential voltage VSS for driving light-emitting elements LD of the display panel 10 from the main power and supply them to a high-potential voltage line VDDL and a low-potential voltage line VSSL of the display panel 10. In addition, the power supply circuit 50 may generate and supply driving voltages for driving the driving circuit 20 and the scan driving unit 30 from the main power.

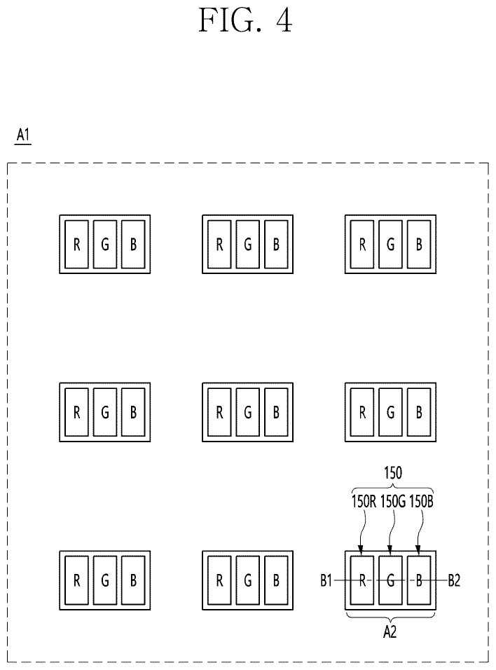

FIG. 4 is an enlarged view of the first panel region in the display device of FIG. 3.

Referring to FIG. 4, the display device 100 of the embodiment may be manufactured by mechanically and electrically connecting a plurality of panel areas such as the first panel region Al by tiling.

The first panel region Al may comprise a plurality of semiconductor light-emitting elements 150 disposed for each unit pixel (PX of FIG. 2).

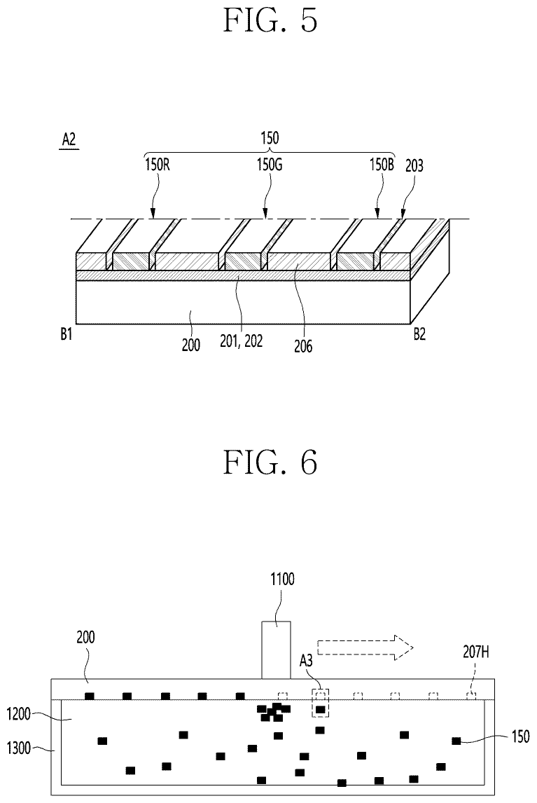

FIG. 5 is an enlarged view of the region A2 of FIG. 4.

Referring to FIG. 5, the display device 100 of the embodiment may comprise a substrate 200, assembly wirings 201 and 202, an insulating layer 206, and a plurality of semiconductor light-emitting elements 150. More components may be included than these.

The assembly wiring may comprise a first assembly wiring 201 and a second assembly wiring 202 that are spaced apart from each other. The first assembly wiring 201 and the second assembly wiring 202 may be provided to generate a dielectrophoretic force (DEP force) to assemble the semiconductor light-emitting element 150. For example, the semiconductor light-emitting element 150 may be one of a lateral-type semiconductor light-emitting element, a flip-chip type semiconductor light-emitting element, and a vertical-type semiconductor light-emitting element.

The semiconductor light-emitting element 150 may comprise a red semiconductor light-emitting element 150, a green semiconductor light-emitting element 150G, and a blue semiconductor light-emitting element 150B to form a unit pixel, but is not limited thereto, and may also comprise a red phosphor and a green phosphor to implement red and green, respectively.

The substrate 200 may be a support member that supports components disposed on the substrate 200 or a protective member that protects the components.

The substrate 200 may be a rigid substrate or a flexible substrate. The substrate 200 may be formed of sapphire, glass, silicon, or polyimide. In addition, the substrate 200 may comprise a flexible material such as polyethylene naphthalate (PEN), polyethylene terephthalate (PET). In addition, the substrate 200 may be a transparent material, but is not limited thereto. The substrate 200 may function as a support substrate in a display panel, and may also function as an assembly substrate when self-assembling a light-emitting element.

The substrate 200 may be a backplane equipped with circuits, such as transistors ST and DT, capacitors Cst, signal wiring, etc., within the subpixels PX1, PX2, and PX3 illustrated in FIGS. 2 and 3, but is not limited thereto.

The insulating layer 206 may comprise an insulating and flexible organic material, such as polyimide, PAC, PEN, PET, polymer, etc., or an inorganic material, such as silicon oxide (SiO₂) or silicon nitride series (SiNx), and may be formed integrally with the substrate 200 to form a single substrate.

The insulating layer 206 may be a conductive adhesive layer having adhesiveness and conductivity, and the conductive adhesive layer may have flexibility to enable a flexible function of the display device. For example, the insulating layer 206 may be a conductive adhesive layer such as an anisotropic conductive film (ACF) or an anisotropic conductive medium, a solution containing conductive particles, etc. The conductive adhesive layer may be a layer that is electrically conductive in a vertical direction relative to the thickness, or electrically insulating in a horizontal direction relative to the thickness.

The insulating layer 206 may comprise an assembly hole 203 for inserting a semiconductor light-emitting element 150. Therefore, when self-assembling, the semiconductor light-emitting element 150 may be easily inserted into the assembly hole 203 of the insulating layer 206. The assembly hole 203 may be named an insertion hole, a fixing hole, an alignment hole, etc. The assembly hole 203 may also be named a hole.

The assembly hole 203 may be named a hole, a home, a groove, a recess, a pocket, etc.

The assembly hole 203 may be different depending on the shape of the semiconductor light-emitting element 150. For example, the red semiconductor light-emitting element, the green semiconductor light-emitting element, and the blue semiconductor light-emitting element each have different shapes, and may have an assembly hole 203 having a shape corresponding to each shape of these semiconductor light-emitting elements. For example, the assembly hole 203 may comprise a first assembly hole for assembling the red semiconductor light-emitting element, a second assembly hole for assembling the green semiconductor light-emitting element, and a third assembly hole for assembling the blue semiconductor light-emitting element. For example, the red semiconductor light-emitting element may have a circular shape, the green semiconductor light-emitting element may have a first elliptical shape having a first minor axis and a first major axis, and the blue semiconductor light-emitting element may have a second elliptical shape having a second minor axis and a second major axis, but is not limited thereto. The second major axis of the elliptical shape of the blue semiconductor light-emitting element may be longer than the first major axis of the elliptical shape of the green semiconductor light-emitting element, and the second minor axis of the elliptical shape of the blue semiconductor light-emitting element may be shorter than the first minor axis of the elliptical shape of the green semiconductor light-emitting element.

Meanwhile, the method of mounting the semiconductor light-emitting element 150 on the substrate 200 may comprise, for example, a self-assembly method (FIG. 6) and a transfer method.

FIG. 6 is a drawing illustrating an example of assembling a light-emitting element according to an embodiment onto a substrate by a self-assembly method.

Based on FIG. 6, an example of assembling a semiconductor light-emitting element according to an embodiment onto a display panel by a self-assembly method using an electromagnetic field will be described.

The assembled substrate 200 described below may also function as a panel substrate in a display device after assembling the light-emitting element, but the embodiment is not limited thereto.

Referring to FIG. 6, the semiconductor light-emitting element 150 may be put into a chamber 1300 filled with a fluid 1200, and the semiconductor light-emitting element 150 may be moved to the assembly substrate 200 by a magnetic field generated from the assembly device 1100. At this time, the semiconductor light-emitting element 150 adjacent to the assembly hole 207H of the assembly substrate 200 may be assembled into the assembly hole 207H by the DEP force caused by the electric field of the assembly wirings. The fluid 1200 may be water such as ultrapure water, but is not limited thereto. The chamber may be named a tank, a container, a vessel, etc.

After the semiconductor light-emitting element 150 is put into the chamber 1300, the assembly substrate 200 may be disposed on the chamber 1300. According to an embodiment, the assembly substrate 200 may also be put into the chamber 1300.

Meanwhile, the first assembly wiring 201 and the second assembly wiring 202 form an electric field as an AC voltage is applied, and the semiconductor light-emitting element 150 put into the assembly hole 207H may be fixed by the DEP force caused by the electric field. The gap between the first assembly wiring 201 and the second assembly wiring 202 may be smaller than the width of the semiconductor light-emitting element 150 and the width of the assembly hole 207H, and the assembly position of the semiconductor light-emitting element 150 may be fixed more precisely using the electric field.

An insulating layer 215 is formed on the first assembly wiring 201 and the second assembly wiring 202 to protect the first assembly wiring 201 and the second assembly wiring 202 from the fluid 1200 and prevent leakage of current flowing in the first assembly wiring 201 and the second assembly wiring 202. For example, the insulating layer 215 may be formed of a single layer or multiple layers of an inorganic insulator such as silica or alumina, or an organic insulator. The insulating layer 215 may have a minimum thickness to prevent damage to the first assembly wiring 201 and the second assembly wiring 202 during assembly of the semiconductor light-emitting element 150, and may have a maximum thickness to stably assemble the semiconductor light-emitting element 150.

A partition wall 207 may be formed on the upper part of the insulating layer 215. A part of the partition wall 207 may be positioned on the upper part of the first assembly wiring 201 and the second assembly wiring 202, and the remaining portion may be positioned on the upper part of the assembly substrate 200.

Meanwhile, when manufacturing the assembly substrate 200, a part of the partition wall 206 formed on the upper part of the insulating layer 215 are removed, so that an assembly hole 207H in which each of the semiconductor light-emitting elements 150 is coupled and assembled to the assembly substrate 200 may be formed.

An assembly hole 207H in which the semiconductor light-emitting elements 150 are coupled is formed in the assembly substrate 200, and a surface on which the assembly hole 207H is formed may be in contact with a fluid 1200. The assembly hole 207H may guide an accurate assembly position of the semiconductor light-emitting element 150.

Meanwhile, the assembly hole 207H may have a shape and size corresponding to the shape of the semiconductor light-emitting element 150 to be assembled at a corresponding position. Accordingly, another semiconductor light-emitting element may be assembled in the assembly hole 207H, or a plurality of semiconductor light-emitting elements can be prevented from being assembled.

Referring back to FIG. 6, after the assembly substrate 200 is disposed in the chamber, the assembly device 1100 applying a magnetic field may move along the assembly substrate 200. The assembly device 1100 may be a permanent magnet or an electromagnet.

The assembly device 1100 may move in contact with the assembly substrate 200 to maximize a region affected by the magnetic field within the fluid 1200. Depending on the embodiment, the assembly device 1100 may comprise a plurality of magnetic substances or may comprise a magnetic substance of a size corresponding to the assembly substrate 200. In this instance, the movement distance of the assembly device 1100 may be limited within a predetermined range.

The semiconductor light-emitting element 150 within the chamber 1300 may move toward the assembly device 1100 and the assembly substrate 200 by the magnetic field generated by the assembly device 1100.

The semiconductor light-emitting element 150 may be fixed by entering the assembly hole 207H by the DEP force formed by the electric field between the assembly wirings 201 and 202 while moving toward the assembly device 1100.

Specifically, the first and second assembly wirings 201 and 202 may form an electric field by an AC power source, and the DEP force may be formed between the assembly wirings 201 and 202 by this electric field. The semiconductor light-emitting element 150 may be fixed to the assembly hole 207H on the assembly substrate 200 by this DEP force.

At this time, a predetermined solder layer (not illustrated) may be formed between the semiconductor light-emitting element 150 assembled on the assembly hole 207H of the assembly substrate 200 and the assembly wirings 201 and 202, thereby improving the bonding strength of the semiconductor light-emitting element 150.

In addition, a molding layer (not illustrated) may be formed in the assembly hole 207H of the assembly substrate 200 after assembly. The molding layer may be a transparent resin or a resin containing a reflective material or a scattering material.

Since the time required for each semiconductor light-emitting element to be assembled on the substrate may be drastically shortened by the self-assembly method using the electromagnetic field described above, a large-area high-pixel display may be implemented more quickly and economically.

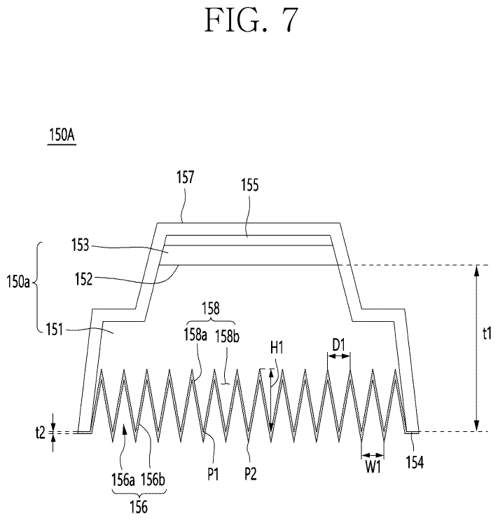

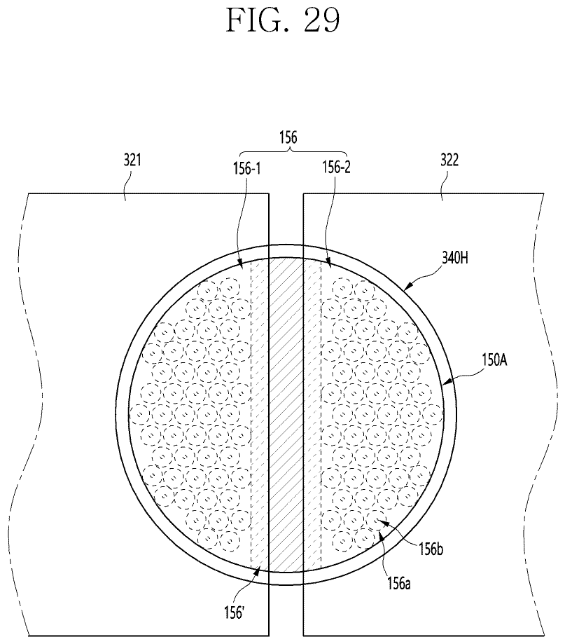

Hereinafter, various embodiments for solving the above-described problem will be described with reference to FIGS. 7 to 44. Any description omitted below may be easily understood from the description described above with respect to FIGS. 1 to 6 and the corresponding drawings.

### First Embodiment

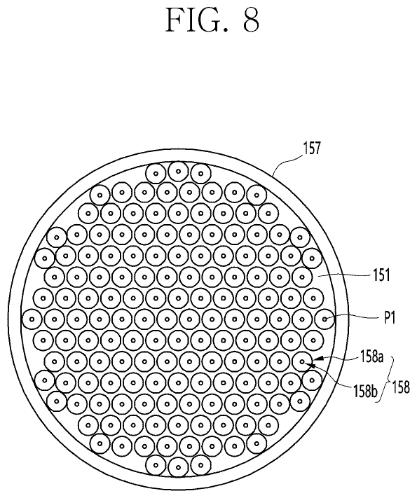

FIG. 7 is a cross-sectional view illustrating a semiconductor light-emitting element according to a first embodiment. FIG. 8 is a bottom view of the semiconductor light-emitting element according to the first embodiment with the first electrode removed.

Referring to FIGS. 7 and 8, the semiconductor light-emitting element 150A according to the first embodiment may comprise a light-emitting layer 150a, a passivation layer 157, a first electrode 154, and a second electrode 155.

The semiconductor light-emitting element 150A according to the first embodiment may be a semiconductor light-emitting element (150R, 150G, and 150B of FIG. 4) that emits light of different colors. The semiconductor light-emitting element 150A according to the first embodiment may be a vertical semiconductor light-emitting element in which current flows vertically within the light-emitting layer 150a, but is not limited thereto.

The light-emitting layer 150a may comprise a plurality of semiconductor layers to generate light of a specific color. For example, the light-emitting layer 150a may comprise at least one or more first conductivity type semiconductor layer 151, an active layer 152, and at least one or more second conductivity type semiconductor layer 153. The active layer 152 may be positioned between the first conductivity type semiconductor layer 151 and the second conductivity type semiconductor layer 153. For example, the first conductivity type semiconductor layer 151 may comprise an n-type dopant, and the second conductivity type semiconductor layer 153 may comprise a p-type dopant, but is not limited thereto.

The passivation layer 157 may surround the light-emitting layer 150a. The passivation layer 157 may be disposed on the upper side and surround the lateral part of the light-emitting layer 150a. For example, the passivation layer 157 may not be disposed on the upper side of the light-emitting layer 150a, so that the upper side of the light-emitting layer 150a may be exposed.

The first electrode 154 may be disposed on the lower side of the light-emitting layer 150a, and the second electrode 155 may be disposed on the upper side of the light-emitting layer 150a. For example, the first electrode 154 may be a cathode electrode, the second electrode 155 may be an anode electrode, and current may flow from the second electrode 155 to the light-emitting layer 150a toward the first electrode 154, and light having luminance corresponding to the current may be generated in the light-emitting layer 150a.

The first electrode 154 may be formed of an opaque metal, and the second electrode 155 may be formed of a transparent conductive material. The first electrode 154 may have a multilayer structure. For example, the first electrode 154 may comprise an ohmic contact layer, a magnetic layer, an electrode layer, a bonding layer, an anti-oxidation layer, etc. The second electrode 155 may also have multilayer structure comprising at least one or more layer in addition to a conductive layer made of a conductive material, but is not limited thereto.

Meanwhile, the semiconductor light-emitting element 150A according to the first embodiment may comprise a first non-uniform region 158. The first non-uniform region 158 may be a region forming a non-uniform surface on the lower side of the light-emitting layer 150a. To this end, the lower side of the light-emitting layer 150a may be processed to form the first non-uniform region 158.

The first non-uniform region 158 may comprise a plurality of first negative patterns 158a and a plurality of first protrusions 158b. The first protrusions 158b may be positioned on the first negative pattern 158a.

The first negative pattern 158a may mean a pattern that is recessed into the interior from the lower side of the light-emitting layer 150a. For example, the first negative pattern 158a may be formed on the lower surface of the first conductivity type semiconductor layer 151 of the light-emitting layer 150a. That is, by removing the lower surface of the first conductivity type semiconductor layer 151, the first negative pattern 158a may be formed by recessing into the interior from the lower surface of the first conductivity type semiconductor layer 151 into the interior.

The plurality of first negative patterns 158a may be spaced apart from each other or may be attached to each other. When the plurality of first negative patterns 158a are spaced apart from each other, a region between the first negative patterns 158a may be the lower surface of the first conductivity type semiconductor layer 151.

The first negative pattern 158a may have a ring shape around the first protrusion 158b. That is, by forming a negative pattern along the perimeter of the first protrusion 158b, a first negative pattern 158a having a ring shape may be formed.

A first protrusion 158b may be formed within the first negative pattern 158a formed in this manner. The first negative pattern 158a may be formed along the perimeter of the first protrusion 158b. For example, by removing a second region corresponding to the circumference of the first region without removing the first region corresponding to the first protrusion 158b on the lower surface of the first conductivity type semiconductor layer 151, the first region that is not removed may be formed as the first protrusion 158b, and the removed second region may be formed as the first negative pattern 158a.

The first protrusion 158b may have a first peak P1 at the lowest point. The first peak P1 of the first protrusion 158b may be positioned on the same horizontal line as the lower surface of the first conductivity type semiconductor layer 151. Near the lower surface of the first conductivity type semiconductor layer 151, the material may be relatively more removed, and as it moves inward from the lower surface of the first conductivity type semiconductor layer 151, it may be relatively less removed, such that the first negative pattern 158a may have a maximum width W1 at the lower surface of the first conductivity type semiconductor layer 151, and the width may decrease as it moves inward into the first conductivity type semiconductor layer 151. In addition, the first protrusion 158b may have a first peak P1 at the lower surface of the first conductivity type semiconductor layer 151 and its diameter may increase as it goes inside the first conductivity type semiconductor layer 151. For example, the maximum diameter D1 of the first protrusion 158b and/or the maximum width W1 of the first negative pattern 158a may be 100 nm or less.

As will be explained later, the first negative pattern 158a and the first protrusion 158b may be formed simultaneously. That is, by performing an etching process on the lower surface of the first conductivity type semiconductor layer 151, a plurality of first negative patterns 158a may be formed, so that the first conductivity type semiconductor layer is not removed within the first negative pattern 158a and remains to be formed as the first protrusion 158b.

Meanwhile, the first electrode 154 may comprise a second non-uniform region 156. The second non-uniform region 156 may be disposed under the first non-uniform region 158. The shape of the second non-uniform region 156 may reflect the shape of the first non-uniform region 158. That is, the second non-uniform region 156 may have a shape corresponding to the shape of the first non-uniform region 158.

Since the first non-uniform region 158 comprises a plurality of first negative patterns 158a and a plurality of first protrusions 158b, the second non-uniform region 156 may comprise a plurality of second negative patterns 156a and a plurality of second protrusions 156b. In this instance, the plurality of second negative patterns 156a may have a shape corresponding to the shape of the plurality of first negative patterns 158a, respectively. The plurality of second protrusions 156b may have a shape corresponding to the shape of the plurality of first protrusions 158b, respectively.

The second negative pattern 156a may have a shape that is recessed toward the inside of the light-emitting layer 150a. The second protrusions 156b may be formed within the second negative pattern 156a. The second negative pattern 156a may have a ring shape around the second protrusion 156b. That is, the second negative pattern 156a having a ring shape may be formed along the perimeter of the second protrusion 156b.

Since the second protrusion 156b is disposed on the first protrusion 158b, it may have a second peak P2 having a shape corresponding to the shape of the first peak P1 of the first protrusion 158b.

Meanwhile, in the embodiment, as the depth of the first negative pattern 158a of the first non-uniform region 158 or the height H1 of the first protrusion 158b increases, a contact area of the first electrode 154 with the light-emitting layer 150a may increase. As the contact area increases, a surface resistance may decrease, so that the electrical characteristics can be improved.

The first non-uniform region 158 may be formed in the first conductivity type semiconductor layer 151 or the second conductivity type semiconductor layer 153 of the light-emitting layer 150a. The first conductivity type semiconductor layer 151 is a semiconductor layer comprising an n-type dopant and may have a thickness t1 that is very large compared to the thickness of the second conductivity type semiconductor layer 153. For example, the first conductivity type semiconductor layer 151 may have a thickness t1 that is 70% or more of the total thickness of the light-emitting layer 150a. Accordingly, the first negative pattern 158a or the first protrusion 158b of the first non-uniform region 158 may be formed in the first conductivity type semiconductor layer 151.

Meanwhile, since the first electrode 154 has a very thin thickness t2 and the height H1 of the first protrusion 158b of the first non-uniform region 158 or the depth of the first negative pattern 158a is very large, the second negative pattern 156a and the second protrusion 156b may be formed corresponding to the first negative pattern 158a and the second protrusion 156b of the first non-uniform region 158, respectively.

For example, the height H1 of the first protrusion 158b may be 20% to 70% of the thickness t1 of the first conductivity type semiconductor layer 151. As described above, since the thickness t1 of the first conductivity type semiconductor layer 151 is very thick, when the height H1 of the first protrusion 158b is 20% to 70% of the thickness t1 of the first conductivity type semiconductor layer 151, the height H1 of the first protrusion 158b may also be very large. As the height H1 of the first protrusion 158b increases, the depth of the first negative pattern 158a may also increase.

For example, the thickness t2 of the first electrode 154 may be 30% or less of the height H1 of the first protrusion 158b. While the height H1 of the first protrusion 158b is very large, the thickness t2 of the first electrode 154 may be very thin. Accordingly, when the second non-uniform region 156 of the first electrode 154 is formed on the first non-uniform region 158, the second negative pattern 156a and the second protrusion 156b of the second non-uniform region 156 may be formed corresponding to the first negative pattern 158a and the first protrusion 158b of the first non-uniform region 158, respectively.

Meanwhile, as described above, the first electrode 154 may comprise a plurality of metal layers comprising an ohmic contact layer, a magnetic layer, etc. In this instance, the plurality of metal layers may be formed very thinly, each having a thickness of 50 nm or less.

According to an embodiment, the first non-uniform region 158 may be disposed under the light-emitting layer 150a, and the first electrode 154 comprising the second non-uniform region 156 may be disposed under the first non-uniform region 158.

Accordingly, the contact area between the first electrode 154 and the light-emitting layer 150a may be expanded, thereby improving the electrical characteristics. In addition, the light generated in the light-emitting layer 150a may be diffusely reflected by the first non-uniform region 158, thereby improving the light emission efficiency. In addition, the area of the magnetic layer included in the first electrode 154 during self-assembly may increase, thereby improving the assembly rate, and since the DEP force for self-assembly increases, a low voltage may be applied, thereby reducing power consumption.

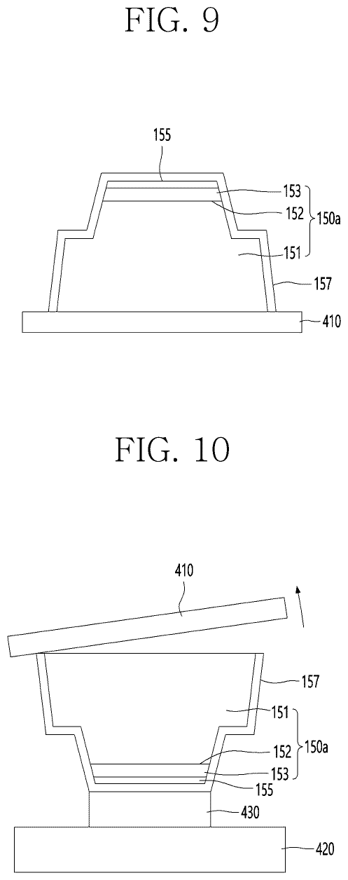

FIGS. 9 to 17 illustrate a method for manufacturing a semiconductor light-emitting element according to the first embodiment.

As illustrated in FIG. 9, the light-emitting layer 150a may be deposited on a growth substrate 410, and the second electrode 155 may be formed on the light-emitting layer 150a, and then a mesa etching process may be performed so that a plurality of light-emitting layers 150a may be separated in chip units. Thereafter, a passivation layer 157 may be formed around the light-emitting layer 150a. The light-emitting layer 150a may comprise at least one or more first conductivity type semiconductor layer 151, an active layer 152 on the first conductivity type semiconductor layer 151, and at least one or more second conductivity type semiconductor layer 153 on the active layer 152.

As illustrated in FIG. 10, the growth substrate 410 may be bonded to the temporary substrate. That is, the passivation layer 157 on the growth substrate 410 may be bonded to a sacrificial layer on the temporary substrate 420. The sacrificial layer may be a metal or an organic material that is to be removed later. Thereafter, the growth substrate 410 may be removed through the LLO process.

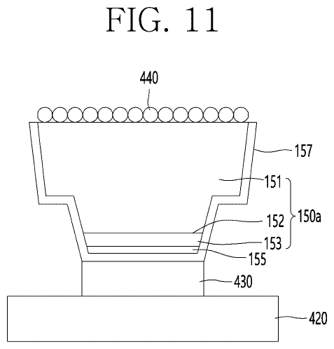

As illustrated in FIG. 11, particles 440 may be applied on the upper surface of the light-emitting layer 150a exposed by removing the growth substrate 410. The particles 440 may be formed of a metal or silicon-based material, but are not limited thereto. In the drawing, the particles 440 have a spherical shape, but may have other shapes. In the drawing, the particles 440 are illustrated as being in contact with each other, but the particles 440 may not be in contact with each other, or some particles 440 may be in contact with each other and other particles 440 may not be in contact with each other. The size of the particles 440 may be several nanometers or less.

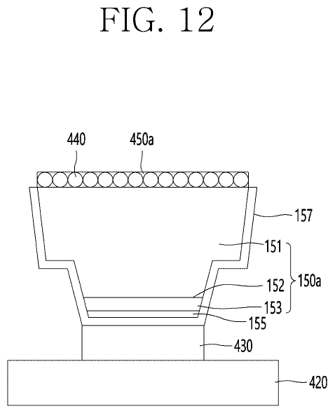

As illustrated in FIG. 12, a fixed film 450a may be formed on the particles 440. The fixed film 450a may comprise an inorganic material such as SiO₂ or SiNx, but is not limited thereto. The fixed film 450a may be formed between the particles 440 and under the particles 440. The particles 440 may be firmly fixed on the light-emitting layer 150a through the fixed film 450a.

Although the drawing illustrates that the fixed film 450a is formed on the particles 440, the fixed film 450a may not be formed on the particles 440, thereby exposing the particles 440.

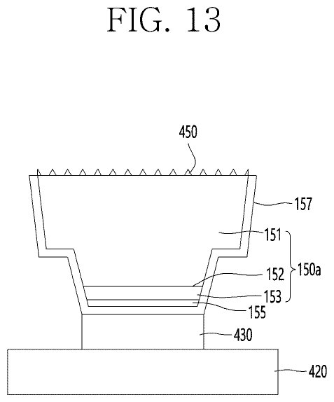

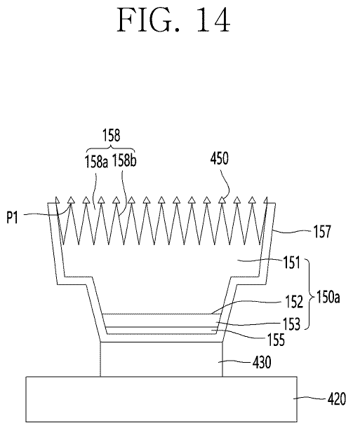

As illustrated in FIG. 13, the fixed film 450a positioned on the particles 440 may be removed, and the particles 440 may be also removed, so that the fixed film 450a formed under the particles 440 may be formed as a pattern mask 450 corresponding to the shape of the particles 440. For example, the fixed film 450a may be removed through dry etching, and the particles 440 may be removed through wet etching, but is not limited thereto.

The pattern mask 450 may have a structure in which patterns are formed between the particles 440 and no pattern is formed under the particles 440.

As illustrated in FIG. 14, an etching process may be performed using the pattern mask 450, so that a first non-uniform region 158 comprising a plurality of first negative patterns 158a and a plurality of first protrusions 158b may be formed on one surface of the light-emitting layer 150a.

The first conductivity type semiconductor layer 151 of the light-emitting layer 150a corresponding to the regions between the patterns of the pattern mask 450 may be removed, but the first conductivity type semiconductor layer 151 of the light-emitting layer 150a corresponding to the patterns of the pattern mask 450 may not be removed. While the etching process is continuously performed, the first conductivity type semiconductor layer 151 corresponding to the patterns of the pattern mask 450 may also be over-etched, so that the first peak P1 may be formed at the vertex of the first protrusion 158b. Meanwhile, the deepest bottom of the first negative pattern 158a may become increasingly difficult to etch, so that a furrow or a valley may be formed.

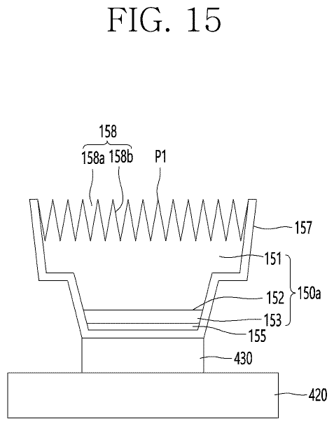

As illustrated in FIG. 15, the pattern mask 450 may be removed.

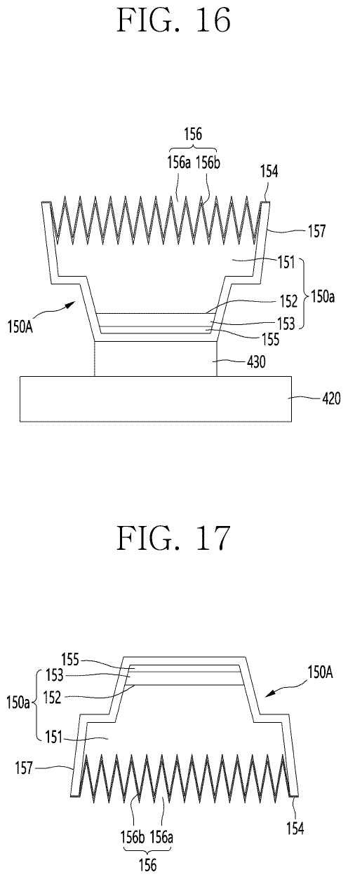

As illustrated in FIG. 16, the first electrode 154 may be formed on the first non-uniform region 158. In this instance, the first electrode 154 may comprise a second non-uniform region 156 having a shape corresponding to the shape of the first non-uniform region 158. That is, the second non-uniform region 156 may also comprise a plurality of second negative patterns 156a and a plurality of second protrusions 156b. The plurality of second negative patterns 156a may have a shape corresponding to the shape of the plurality of first negative patterns 158a, respectively. The plurality of second protrusions 156b may have a shape corresponding to the shape of the plurality of first protrusions 158b, respectively.

As described above, a semiconductor light-emitting element 150A according to the first embodiment, which is composed of the light-emitting layer 150a, the passivation layer 157, the first electrode 154, and the second electrode 155, may be manufactured.

As illustrated in FIG. 17, the semiconductor light-emitting element 150A according to the first embodiment may be separated from the temporary substrate 420 by removing the sacrificial layer using an etchant.

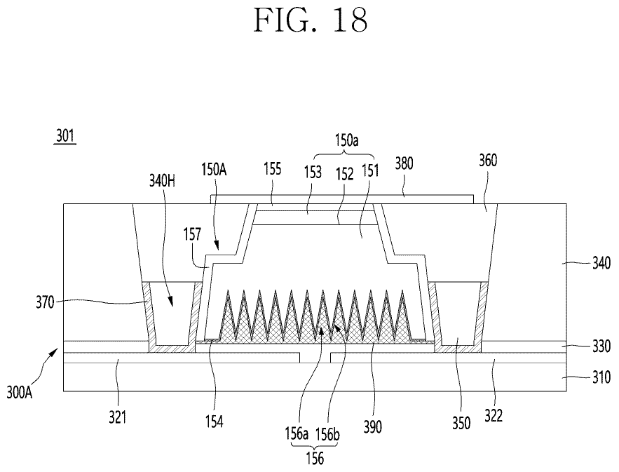

FIG. 18 is a cross-sectional view illustrating a display device according to the first embodiment.

Referring to FIG. 18, the display device 301 according to the first embodiment may comprise a backplane substrate 300A, a semiconductor light-emitting element 150A, a fixing member 390, a connecting electrode 370, and an electrode wiring 380.

The backplane substrate 300A may be a base substrate for manufacturing the display device 301 by performing a post-process such as a self-assembly process and an electrical connection. That is, the semiconductor light-emitting element 150A may be assembled on the backplane substrate 300A through a self-assembly process, and an electrical connection to the semiconductor light-emitting element 150A may be formed through a post-process, thereby manufacturing the display device 301 according to the first embodiment.

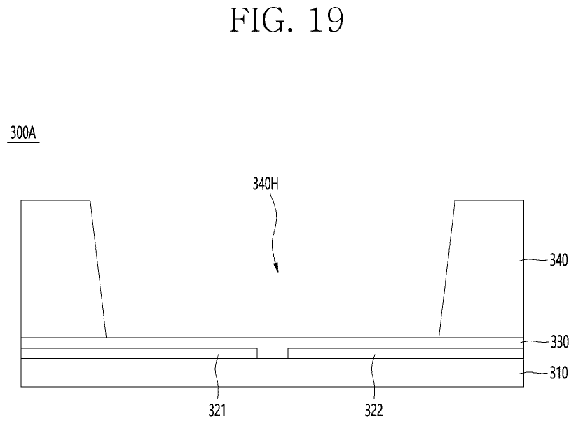

The backplane substrate 300A may comprise a substrate 310, a first assembly wiring 321, a second assembly wiring 322, a first insulating layer 330, and a partition wall 340, as illustrated in FIG. 19. For example, the backplane substrate 300A may be manufactured by forming the first assembly wiring 321, the second assembly wiring 322, the first insulating layer 330, and the partition wall 340 on the substrate 310.

The substrate 310 may be a support substrate for supporting components of the display device 301 according to the first embodiment, such as the semiconductor light-emitting element 150A, the connecting electrode 370, the second insulating layer 350, the third insulating layer 360, the electrode wiring 380, etc., and may be referred to as a lower substrate or a display substrate. Although not illustrated, an upper substrate may be disposed on the electrode wiring 380, but is not limited thereto.

The first assembly wiring 321 may be disposed on the substrate 310. The second assembly wiring 322 may be disposed on the substrate 310.

For example, the first assembly wiring 321 and the second assembly wiring 322 may be disposed on the same layer, respectively. For example, the first and second assembly wirings 321 and 322 may be in contact with the upper surface of the substrate 310, but is not limited thereto. For example, the first assembly wiring 321 and the second assembly wiring 322 may be disposed on the same layer, respectively. For example, the first assembly wiring 321 and the second assembly wiring 322 may be disposed parallel to each other, respectively. The first assembly wiring 321 and the second assembly wiring 322 may play a role in assembling the semiconductor light-emitting element 150A into the assembly hole 340H using a self-assembly method. That is, when self-assembling, an electric field may be generated between the first assembly wiring 321 and the second assembly wiring 322 by the AC voltage supplied to the first assembly wiring 321 and the second assembly wiring 322, and the semiconductor light-emitting element 150A moving by the assembly device (1100 of FIG. 6) may be assembled into the assembly hole 340H by the DEP force formed by the electric field. The assembly hole 340H may have a diameter greater than the diameter of the semiconductor light-emitting element 150A.

The first assembly wiring 321 and the second assembly wiring 322 may each comprise a plurality of metal layers. Although not illustrated, the first assembly wiring 321 and the second assembly wiring 322 may each comprise a main wiring and an auxiliary electrode. The main wiring of each of the first assembly wiring 321 and the second assembly wiring 322 may be disposed long along one direction of the substrate 310. The auxiliary electrode of each of the first assembly wiring 321 and the second assembly wiring 322 may extend from the main wiring toward the assembly hole 340H. The auxiliary electrodes may be electrically connected to the main wirings. The main wiring may be disposed on the auxiliary wiring so that the lower surface of the main wiring may be in contact with the upper surface of the auxiliary wiring, but is not limited thereto.

Meanwhile, although not illustrated, the first assembly wiring 321 and the second assembly wiring 322 may be disposed on different layers.

The first insulating layer 330 may be disposed on the first assembly wiring 321 and the second assembly wiring 322. For example, the first insulating layer 330 may be made of an inorganic material or an organic material. For example, the first insulating layer 330 may be made of a material having a permittivity related to the DEP force. For example, the higher the permittivity of the first insulating layer 330, the greater the DEP force, but is not limited thereto. The first insulating layer 330 may prevent the fluid from directly being in contact with the first assembly wiring 321 or the second assembly wiring 322 and corroding them by the assembly hole 340H of the partition wall 340 formed thereafter during self-assembly.

Although the drawing illustrates that the first insulating layer 330 is removed within the assembly hole 340H, the first insulating layer 330 may remain unremoved within the assembly hole 340H in the backplane substrate 300A. The process of removing the first insulating layer 330 within the assembly hole 340H may be performed after the semiconductor light-emitting element 150A is assembled into the assembly hole 340H. The removal of the first insulating layer 330 within the assembly hole 340H may be for the purpose of electrically connecting the connecting electrode 370 with the first assembly wiring 321 and/or the second assembly wiring 322.

The partition wall 340 may be disposed on the first insulating layer 330. The first insulating layer 330 may have an assembly hole 340H. The assembly hole 340H may be formed in each of the plurality of subpixels PX1, PX2, and PX3 of the plurality of pixels (PX in FIG. 2). That is, one assembly hole 340H may be formed per each of the subpixels PX1, PX2, and PX3, but is not limited thereto. For example, the first insulating layer 330 may be exposed within the assembly hole 340H. For example, the bottom surface of the assembly hole 340H may be the upper surface of the first insulating layer 330.

The height (or thickness) of the partition wall 340 may be determined in consideration of the thickness of the semiconductor light-emitting element 150A.

Meanwhile, although not illustrated, pixel circuits and signal lines connected to each pixel circuit may be provided for each of a plurality of pixels on the backplane substrate 300A. The signal lines may comprise the data lines DI to Dm, the scan lines S1 to Sn, the high-potential voltage line VDDL, the low-potential voltage line VSSL, etc., as illustrated in FIGS. 2 and 3.

A self-assembly process may be performed on a backplane substrate 300A configured as described above, so that a plurality of semiconductor light-emitting elements 150A may be assembled into a plurality of subpixels PX1, PX2, and PX3 of each of a plurality of pixels PX on the substrate 310.

As an example, a plurality of red semiconductor light-emitting elements, a plurality of green semiconductor light-emitting elements, and a plurality of blue semiconductor light-emitting elements may be sequentially assembled into a plurality of subpixels PX1, PX2, and PX3 of each of a plurality of pixels PX on the substrate 310.

As another example, a plurality of red semiconductor light-emitting elements, a plurality of green semiconductor light-emitting elements, and a plurality of blue semiconductor light-emitting elements may be simultaneously assembled into a plurality of subpixels PX1, PX2, and PX3 of each of a plurality of pixels PX on the substrate 310. To this end, a plurality of red semiconductor light-emitting elements, a plurality of green semiconductor light-emitting elements, and a plurality of blue semiconductor light-emitting elements may be dropped into a fluid in a chamber and mixed. Subsequently, the same self-assembly process may be performed so that a plurality of red semiconductor light-emitting elements, a plurality of green semiconductor light-emitting elements, and a plurality of blue semiconductor light-emitting elements may be simultaneously assembled into a plurality of subpixels PX1, PX2, and PX3 of each of a plurality of pixels PX on the substrate 310.

For the simultaneous self-assembly, each of the red semiconductor light-emitting elements, the green semiconductor light-emitting elements, and the blue semiconductor light-emitting elements may have exclusivity with respect to each other. That is, the shapes or sizes of the red semiconductor light-emitting elements, the green semiconductor light-emitting elements, and the blue semiconductor light-emitting elements may be different. For example, the red semiconductor light-emitting elements may have a circular shape, the green semiconductor light-emitting elements may have a first elliptical shape having a first minor axis and a first major axis, and the blue semiconductor light-emitting elements may have a second elliptical shape. In this instance, the second elliptical shape may have a second minor axis smaller than the first minor axis and a second major axis greater than the first major axis.

Meanwhile, the semiconductor light-emitting element 150A may be disposed in the assembly hole 340H. The semiconductor light-emitting element 150A may be the semiconductor light-emitting element 150A illustrated in FIG. 7. The semiconductor light-emitting element 150A may be a red semiconductor light-emitting element that generates red light, a green semiconductor light-emitting element that generates green light, or a blue semiconductor light-emitting element that generates blue light.

For example, during self-assembly, the red semiconductor light-emitting element, the green semiconductor light-emitting element, and the blue semiconductor light-emitting element distributed in the same chamber (1300 of FIG. 6) may be simultaneously moved by the same assembly device 1100, and may be simultaneously assembled in the assembly hole 340H of each corresponding subpixel (PX1, PX2, PX3 of FIG. 2).

When the size of the assembly hole 340H of each of the subpixels (PX1, PX2, PX3 in FIG. 2) is the same, the red semiconductor light-emitting element, the green semiconductor light-emitting element, and the blue semiconductor light-emitting element may not be assembled into the assembly hole 340H in which they are to be assembled, but may be assembled into different assembly holes 340H. To solve this problem, the shapes of the red semiconductor light-emitting element, the green semiconductor light-emitting element, and the blue semiconductor light-emitting element may be different, and the assembly hole 340H may be formed to correspond to the different shapes of the red semiconductor light-emitting element, the green semiconductor light-emitting element, and the blue semiconductor light-emitting element. That is, the exclusivity between the semiconductor light-emitting elements may be increased, thereby preventing assembly defects or color mixing defects.

For example, the shape of the red semiconductor light-emitting element may be circular, the shape of the green semiconductor light-emitting element may be a first elliptical shape having a first minor axis and a first major axis, and the shape of the blue semiconductor light-emitting element may be a second elliptical shape having a second minor axis smaller than the first minor axis and a second major axis greater than the first major axis.

The semiconductor light-emitting element 150A may be disposed in the assembly hole 340H to generate color light. As described above, the semiconductor light-emitting element 150A may comprise one of a red semiconductor light-emitting element, a green semiconductor light-emitting element, and a blue semiconductor light-emitting element. For example, the red semiconductor light-emitting element may be disposed in the first subpixel (PX1 of FIG. 2), the green semiconductor light-emitting element may be disposed in the second subpixel PX2, and the blue semiconductor light-emitting element may be disposed in the third subpixel PX3. Accordingly, a full-color image may be displayed by the red light emitted from the first subpixel PX1, the green light emitted from the second subpixel PX2, and the blue light emitted from the third subpixel PX3.

The semiconductor light-emitting element 150A of the embodiment may be a vertical semiconductor light-emitting element, but is not limited thereto. In this instance, after the semiconductor light-emitting element is assembled in the assembly hole 340H, the first electrode 154 of the semiconductor light-emitting element may be electrically connected to a lower electrode wiring, i.e., the first assembly wiring 321 or the second assembly wiring 322, and the upper side of the semiconductor light-emitting element 150A may be electrically connected to the electrode wiring 380.

Meanwhile, the semiconductor light-emitting element 150A assembled in the assembly hole 340H through self-assembly may be fixed to the assembly hole 340H before forming the electrical connection. To this end, the fixing member 390 may be disposed in the assembly hole 340H of the backplane substrate 300A. For example, the fixing member 390 may be disposed between the semiconductor light-emitting element 150A and the bottom surface of the assembly hole 340H. The fixing member 390 may comprise an organic material, but is not limited thereto. The semiconductor light-emitting element 150A may be fixed within the assembly hole 340H by the fixing member 390. That is, the fixing member 390 may fix the semiconductor light-emitting element 150A to the first insulating layer 330 within the assembly hole 340H.

The fixing member 390 may be formed by the following process. First, an insulating film may be formed on the substrate 310 comprising the assembly hole 340H. In this instance, the insulating film may be formed around the semiconductor light-emitting element 150A within the assembly hole 340H. Thereafter, the insulating film on the substrate 310 may be removed through an etching process. At this time, since the semiconductor light-emitting element 150A serves as a mask, the insulating film positioned under the semiconductor light-emitting element 150A remains without being removed, and may be formed as the fixing member 390. That is, the insulating film positioned under the semiconductor light-emitting element 150A may become the fixing member 390. Accordingly, the fixing member 390 may have a shape corresponding to the shape of the semiconductor light-emitting element 150A. For example, the diameter (or width) of the fixing member 390 may be the same as the diameter (or width) of the semiconductor light-emitting element 150A, but is not limited thereto.

As described above, a first electrode 154 comprising a second non-uniform region 156 may be formed on the lower side of the semiconductor light-emitting element 150A. That is, the second non-uniform region 156 may comprise a plurality of second negative patterns 156a and a plurality of second protrusions 156b. In this instance, the fixing member 390 may be disposed on the plurality of second negative patterns 156a, as illustrated in FIG. 18. For example, the fixing member 390 may be in contact with the second negative pattern 156a within the plurality of second negative patterns 156a. Accordingly, since the contact area between the fixing member 390 and the first electrode 154 is significantly increased, the semiconductor light-emitting element 150A can be more firmly fixed to the first insulating layer 330 of the backplane substrate 300A by the fixing member 390, so that the fixing property of the semiconductor light-emitting element 150A can be further strengthened.

Meanwhile, the connecting electrode 370 may be disposed in the assembly hole 340H. The connecting electrode 370 may be electrically connected to the lateral part of the semiconductor light-emitting element 150A within the assembly hole 340H. In addition, the connecting electrode 370 may be electrically connected to the first assembly wiring 321 and/or the second assembly wiring 322 within the assembly hole 340H. Accordingly, the connecting electrode 370 may electrically connect the lateral part of the semiconductor light-emitting element 150A to the first assembly wiring 321 and/or the second assembly wiring 322.

For example, the connecting electrode 370 may be formed of at least one or more layer having excellent electrical conductivity. For example, the connecting electrode 370 may comprise a first layer comprising molybdenum (Mo), a second layer comprising aluminum (Al), and a third layer comprising molybdenum (Mo).

Meanwhile, although not illustrated, the connecting electrode 370 may be disposed along the perimeter of the semiconductor light-emitting element 150A within the assembly hole 340H. For example, the connecting electrode 370 may be disposed between the inner side of the assembly hole 340H and the outer side of the semiconductor light-emitting element 150A.

Meanwhile, the display device 301 according to the first embodiment may comprise a second insulating layer 350 and a third insulating layer 360. The second insulating layer 350 and the third insulating layer 360 may comprise an organic material such as PAC, PI, polymer, etc., or an inorganic material such as SiO2, SiNX, etc. For example, the second insulating layer 350 and/or the third insulating layer 360 may comprise a photosensitive material. The second insulating layer 350 and the third insulating layer 360 may comprise the same material, but is not limited thereto.

The second insulating layer 350 may serve as a stopper that determines the height of the connecting electrode 370. That is, the height of the connecting electrode 370 may be formed as much as the height of the second insulating layer 350. That is, when the height of the second insulating layer 350 is increased, the height of the connecting electrode 370 may also be increased. The uppermost side of the connecting electrode 370 may be positioned lower than the active layer 152 of the semiconductor light-emitting element 150A, thereby preventing the possibility of an electrical short circuit between the connecting electrode 370 and the active layer 152.

The third insulating layer 360 may be a fixing layer for fixing the semiconductor light-emitting element 150A or a planarizing layer for easy formation of layers formed by a post-process. In this instance, the upper surface of the third insulating layer 360 may have a straight plane.

The third insulating layer 360 may be formed only within the assembly hole 340H and may not be formed on the semiconductor light-emitting element 150A. Although not illustrated, the third insulating layer 360 may be formed on the semiconductor light-emitting element 150A. In this instance, the electrode wiring 380 may be electrically connected to the upper side of the semiconductor light-emitting element 150A through the third insulating layer 360. To this end, a contact hole may be formed in the third insulating layer 360 so that the electrode wiring 380 may be formed. Meanwhile, the third insulating layer 360 may be formed on the partition wall 340.

Meanwhile, the electrode wiring 380 may be disposed on the semiconductor light-emitting element 150A. Since the third insulating layer 360 is not formed on the semiconductor light-emitting element 150A, the electrode wiring 380 may be directly connected to the upper side of the semiconductor light-emitting element 150A. That is, the electrode wiring 380 may be in contact with the upper side of the semiconductor light-emitting element 150A, i.e., the upper surface of the second electrode 155, without the interference of the third insulating layer 360. For example, the electrode wiring 380 may be in surface contact with the upper surface of the second electrode 155 of the semiconductor light-emitting element 150A.

Accordingly, the semiconductor light-emitting element 150A may emit light by the voltage supplied to the electrode wiring 380 and the first assembly wiring 321 and/or the second assembly wiring 322.

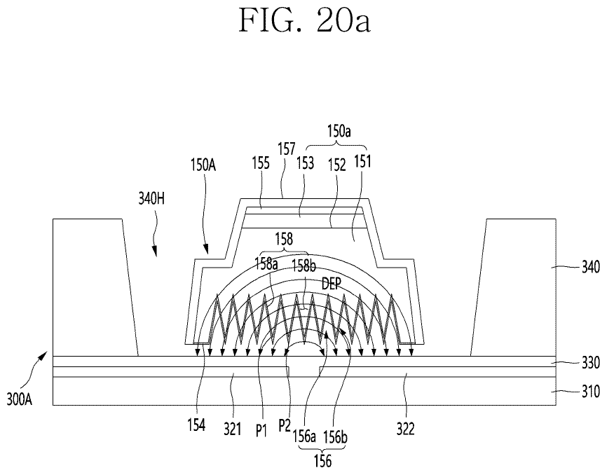

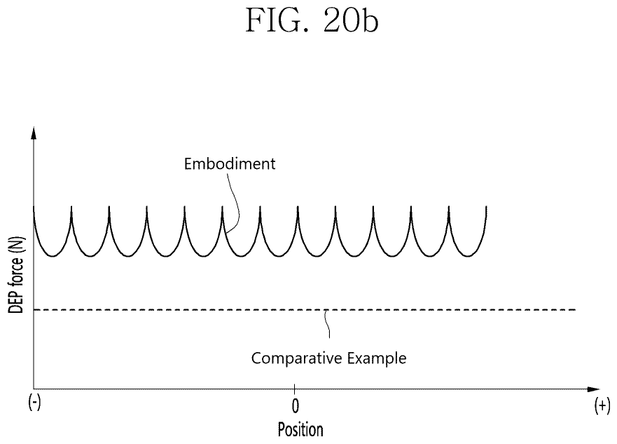

FIGS. 20A to 25 illustrate a method for manufacturing a display device according to the first embodiment.

As illustrated in FIG. 20A, a backplane substrate 300A may be provided. The backplane substrate 300A may be mounted in a chamber for self-assembly. At this time, the semiconductor light-emitting element 150A may be dispersed in the fluid of the chamber.

First, when the magnet moves, the semiconductor light-emitting element 150A, which is affected by the magnetic field of the magnet, may move toward the magnet. As the magnet moves horizontally with respect to the surface of the backplane substrate 300A, the semiconductor light-emitting element 150A may move horizontally with respect to the surface of the backplane substrate 300A, but is not limited thereto.

Thereafter, a DEP force may be formed by applying an AC voltage to the first assembly wiring 321 and the second assembly wiring 322 of the backplane substrate 300A. Since the first assembly wiring 321 and the second assembly wiring 322 are disposed in subpixel units, the DEP force may be formed in each of the plurality of subpixels.

When the semiconductor light-emitting element 150A moving by the magnet passes through the assembly hole 340H of the backplane substrate 300A, the semiconductor light-emitting element 150A may be pulled by the DEP force and assembled into the assembly hole 340H.

As described above, the first electrode 154 of the semiconductor light-emitting element 150A may comprise a second non-uniform region 156 having a plurality of second negative patterns 156a and a plurality of second protrusions 156b. As illustrated in FIG. 20B, a relatively large DEP force may be formed on each of the second protrusions 156b of the first electrode 154. That is, as in the comparative example, when the first electrode 154 does not comprise the second non-uniform region 156, that is, when the first electrode 154 has a straight plane, the DEP force is relatively small. In contrast, in the case where the second non-uniform region 156 having the plurality of second negative patterns 156a and the plurality of second protrusions 156b is included in the first electrode 154 of the semiconductor light-emitting element 150A as in the embodiment, it may be seen that the DEP force is formed significantly compared to the comparative example. In particular, it may be seen that the DEP force is relatively larger in each of the plurality of second protrusions 156b of the first electrode 154.

In this way, when the semiconductor light-emitting element 150A of the embodiment passes through the assembly hole 340H while moving horizontally with respect to the surface of the backplane substrate 300A, an even larger DEP force may be formed in the assembly hole 340H by the plurality of second protrusions 156b included in the first electrode 154 of the semiconductor light-emitting element 150A, so that the semiconductor light-emitting element 150A may be immediately pulled and assembled in the corresponding assembly hole 340H. In addition, the semiconductor light-emitting element 150A may be strongly fixed to the assembly hole 340H by an even greater DEP force. Accordingly, the assembly rate of the semiconductor light-emitting element 150A can be improved, and the detachment of the semiconductor light-emitting element 150A can be prevented, so that the assembly defect can be reduced and the lighting yield can be increased.

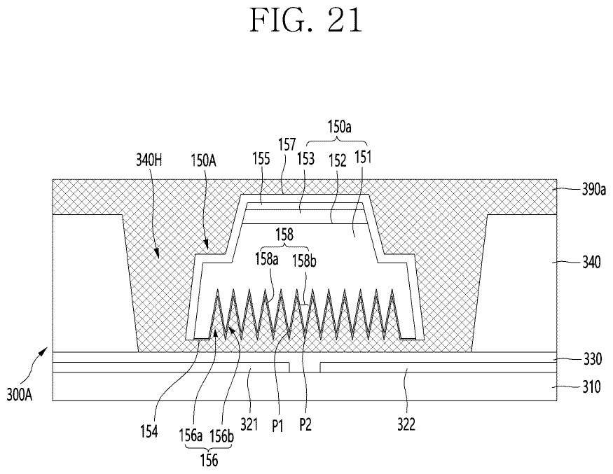

As illustrated in FIG. 21, an insulating film 390a may be formed on the substrate 310. The insulating film 390a may be formed not only on the partition wall 340 but also on the assembly hole 340H.

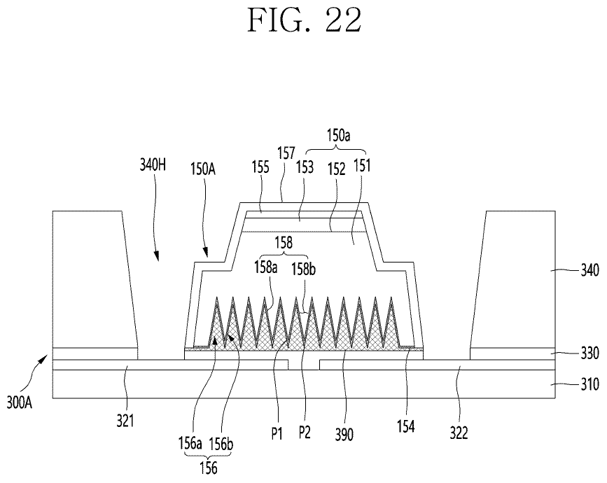

As illustrated in FIG. 22, the insulating film 390a on the substrate 310 may be removed through an etching process. At this time, since the semiconductor light-emitting element 150A serves as a mask, the insulating film 390a positioned under the semiconductor light-emitting element 150A is not removed and remains, so that it may be formed as the fixing member 390. That is, the insulating film 390a positioned under the semiconductor light-emitting element 150A may become the fixing member 390.

As described above, the first electrode 154 provided on the lower side of the semiconductor light-emitting element 150A may comprise a plurality of second negative patterns 156a and a plurality of second protrusions 156b. In this instance, since the fixing member 390 is formed within the plurality of second negative patterns 156a, the contact area between the fixing member 390 and the semiconductor light-emitting element 150A can be significantly increased. Accordingly, since the semiconductor light-emitting element 150A is more firmly fixed to the first insulating layer 330 of the backplane substrate 300A by the fixing member 390, the fixing property of the semiconductor light-emitting element 150A can be further strengthened. Since the semiconductor light-emitting element 150A does not come out of the assembly hole 340H until an electrical connection is formed by a post-process, assembly defect can be prevented and the lighting yield can be improved.

Meanwhile, although not illustrated, an etching process may be performed so that the first insulating layer 330 exposed in the assembly hole 340H may be removed, thereby exposing the first assembly wiring 321 and/or the second assembly wiring 322. At this time, since the semiconductor light-emitting element 150A and the fixing member 390 serve as a mask, the first insulating layer 330 positioned under the fixing member 390 in the assembly hole 340H may not be removed, and the first insulating layer 330 positioned around the semiconductor light-emitting element 150A may be removed.

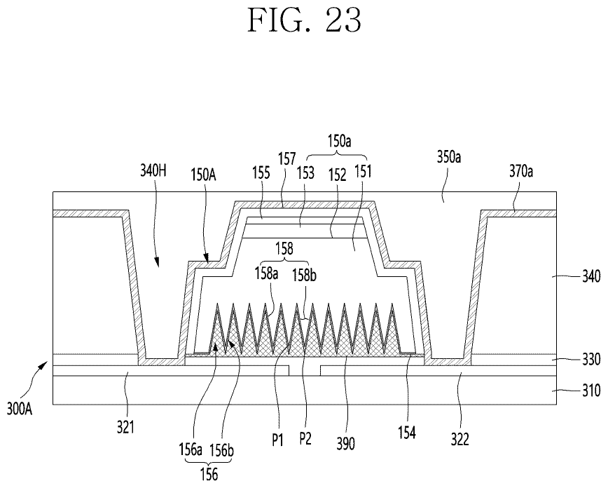

As illustrated in FIG. 23, a metal film 370a may be deposited on the partition wall 340 and the semiconductor light-emitting element 150A. Thereafter, an insulating film 350a may be formed on the metal film 370a.

The insulating film 350a may be formed on the overall region of the substrate 310. The insulating film 350a may be formed of an organic material that is easy to form a thick thickness, but an inorganic material may also be used.

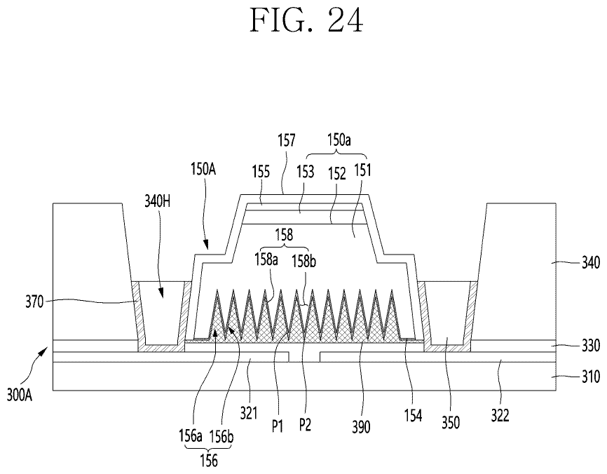

As illustrated in FIG. 24, the upper surface of the insulating film 350a may be removed through an ashing process, so that the upper surface of the insulating film 350a may be positioned within the assembly hole 340H. Thereafter, an etching process may be performed so that the metal film 370a may be etched, so that the connecting electrode 370 may be formed. The second insulating layer 350 may serve as a stopper to prevent the metal film 370a from being etched further under the upper surface of the insulating film 350a.

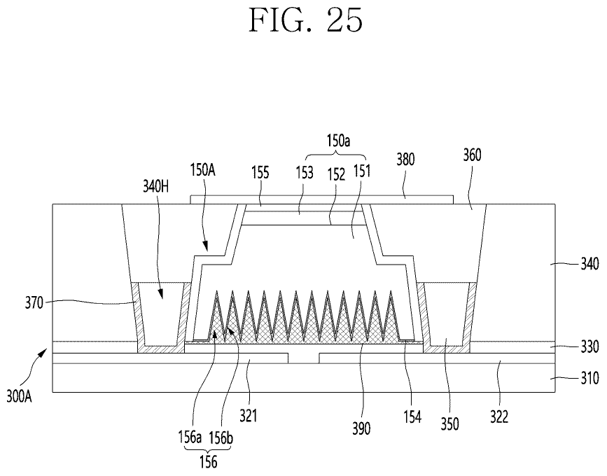

As illustrated in FIG. 25, a third insulating layer 360 may be formed in the assembly hole 340H, and an electrode wiring 380 may be disposed on the upper side of the semiconductor light-emitting element 150A. The electrode wiring 380 may be disposed on the third insulating layer 360. The upper surface of the third insulating layer 360 and the upper surface of the second electrode 155 of the semiconductor light-emitting element 150A may be positioned on the same horizontal line, but is not limited thereto.

A passivation layer 157 may be removed on the upper side of the semiconductor light-emitting element 150A. The removal of the passivation layer 157 may be performed after the fixing member 390 is formed (FIG. 22) or after the connecting electrode 370 is formed (FIG. 24), but is not limited thereto.

### Second Embodiment

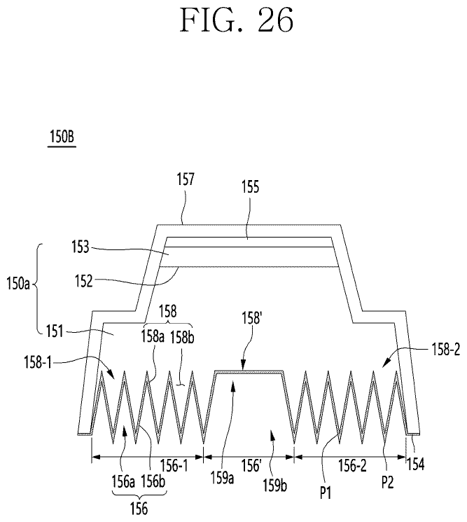

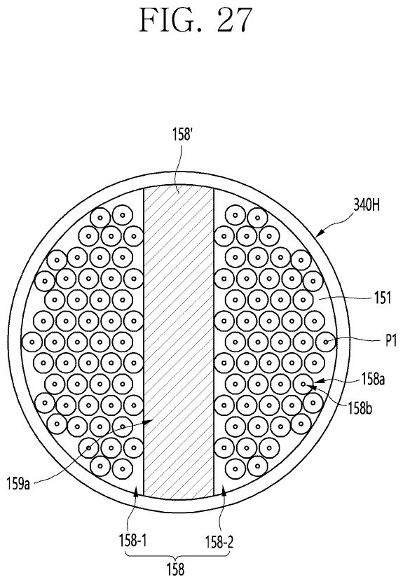

FIG. 26 is a cross-sectional view illustrating a semiconductor light-emitting element according to a second embodiment. FIG. 27 is a bottom view of the semiconductor light-emitting element according to the second embodiment with the first electrode removed.

The second embodiment is the same as the first embodiment except for a first uniform region 158′ and a second uniform region 156′. In the second embodiment, components having the same shape, structure, and/or function as those in the first embodiment are given the same drawing reference numerals, and detailed descriptions thereof are omitted.

Referring to FIGS. 26 and 27, the semiconductor light-emitting element 150B according to the second embodiment may comprise a light-emitting layer 150a, a passivation layer 157, a first non-uniform region 158, a first uniform region 158′, a first electrode 154, and a second electrode 155.

The first non-uniform region 158 and the first uniform region 158′ may be disposed under the light-emitting layer 150a. The first non-uniform region 158 and the first uniform region 158′ may be disposed on a lower side of the light-emitting layer 150a. The first non-uniform region 158 and the first uniform region 158′ may be formed on a lower surface of the first conductivity type semiconductor layer 151. The first non-uniform region 158 and the first uniform region 158′ may be a part of the first conductivity type semiconductor layer 151. That is, by etching the lower surface of the first conductivity type semiconductor layer 151, the first non-uniform region 158 comprising a plurality of first negative patterns 158a and a plurality of first protrusions 158b and the first uniform region 158′ having a first recess may be formed.

The first uniform region 158′ may be disposed long in both directions from the center of the lower side of the light-emitting layer 150a. The first uniform region 158′ may have a plane. The first uniform region 158′ may have a fine roughness depending on the degree of etching, but is not limited thereto. The first uniform region 158′ may have a first recess. That is, by etching inward from the lower side of the light-emitting layer 150a, the first recess may be formed in the first uniform region 158′. Although not illustrated, the lower side of the light-emitting layer 150a may not be etched, that is, the lower surface of the first conductivity type semiconductor layer 151 of the light-emitting layer 150a may be the first uniform region 158′, but is not limited thereto.

The first non-uniform region 158 may comprise a plurality of first negative patterns 158a and a plurality of first protrusions 158b. The first negative patterns 158a and the first protrusions 158b have been described in detail in the first embodiment, so that further description thereof will be omitted.

Meanwhile, the first non-uniform region 158 may be provided with at least one or more. For example, the first non-uniform region 158 may comprise a first-first non-uniform region 158-1 and a first-second non-uniform region 158-2.

The first-first non-uniform region 158-1 may be disposed under a first emission region of the light-emitting layer 150a, and the first-second non-uniform region 158-2 may be disposed under a second emission region of the light-emitting layer 150a. Since the first emission region and the second emission region are spaced apart, the first-first non-uniform region 158-1 and the first-second non-uniform region 158-2 may also be spaced apart. The first emission region and the second emission region are distinguished for convenience of explanation, and the first emission region and the second emission region may be formed integrally as a part of the light-emitting layer 150a.

The first uniform region 158′ may be positioned between the first-first non-uniform region 158-1 and the first-second non-uniform region 158-2. That is, the first-first non-uniform region 158-1 and the first-second non-uniform region 158-2 may be spaced apart from each other with the first uniform region 158′ therebetween. For example, the first-first non-uniform region 158-1 may be positioned on a first side of the first uniform region 158′, and the first-second non-uniform region 158-2 may be positioned on a second side of the first uniform region 158′. That is, the first-first non-uniform region 158-1 and the first-second non-uniform region 158-2 may be disposed on both sides of the lower side of the light-emitting layer 150a, respectively.

The first-first non-uniform region 158-1 and the first-second non-uniform region 158-2 may each comprise a plurality of first negative patterns 158a and a plurality of first protrusions 158b. In this instance, the surface of the first uniform region 158′ may be positioned on the same horizontal line as the bottom of the first negative pattern 158a, but is not limited thereto. As described above, since the first uniform region 158′ has the first recess, the surface of the first uniform region 158′, i.e., the bottom of the first recess, may be positioned on the same horizontal line as the bottom of the first negative pattern 158a.

Although not illustrated, the first uniform region 158′ and the second uniform region 156′ may not have the first recess and the second recess 159b, respectively. When the lower surface of the first conductivity type semiconductor layer 151 is not etched, the lower surface of the first conductivity type semiconductor layer 151 itself becomes the first uniform region 158′, and the second uniform region 156′ of the first electrode 154 may be formed on the first uniform region 158′. In this instance, the surface of the first uniform region 158′ may be positioned on the same horizontal line as the first peak P1 of the first protrusion 158b.

Meanwhile, the first electrode 154 may comprise the second non-uniform region 156 and the second uniform region 156′. The second non-uniform region 156 may have a shape corresponding to the shape of the first non-uniform region 158. The second uniform region 156′ may have a shape corresponding to the shape of the first uniform region 158′.

The second uniform region 156′ may be a second recess 159b corresponding to the first recess. The second uniform region 156′ may be disposed long in both directions at the center of the lower side of the light-emitting layer 150a. The second uniform region 156′ may have a plane.

The second non-uniform region 156 may comprise the second-first non-uniform region 156-1 and the second-second non-uniform region 156-2. The second uniform region 156′ may be positioned between the second-first non-uniform region 156-1 and the second-second non-uniform region 156-2. The second-first non-uniform region 156-1 may have a shape corresponding to the shape of the first-first non-uniform region 158-1. The second-second non-uniform region 156-2 may have a shape corresponding to the shape of the first-second non-uniform region 158-2.

The second-first non-uniform region 156-1 and the second-second non-uniform region 156-2 may each comprise a plurality of second negative patterns 156a and a plurality of second protrusions 156b. In this instance, the surface of the second uniform region 156′ may be positioned on the same horizontal line as the bottom of the second negative pattern 156a, but is not limited thereto. As described above, since the second uniform region 156′ has the second recess 159b, the surface of the second uniform region 156′, i.e., the bottom of the second recess 159b, may be positioned on the same horizontal line as the bottom of the second negative pattern 156a.

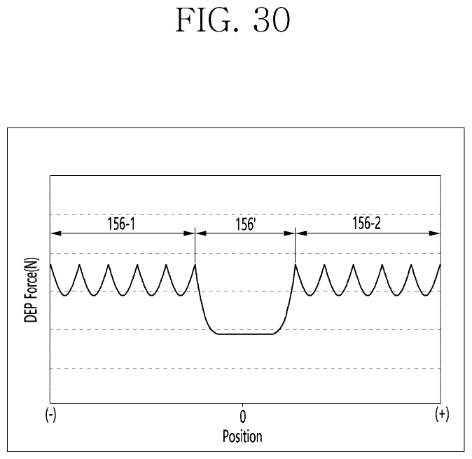

In this way, in case that the second-first non-uniform region 156-1 and the second-second non-uniform region 156-2 of the first electrode 154 are disposed on both sides of the lower side of the light-emitting layer 150a, when the semiconductor light-emitting element 150B according to the second embodiment is positioned in the assembly hole 340H through self-assembly, a relatively large DEP force may be formed in the second protrusions 156b of each of the second-first non-uniform region 156-1 and the second-second non-uniform region 156-2 of the first electrode 154, as illustrated in FIG. 30. In addition, as illustrated in FIG. 30, it may be seen that a larger DEP force is formed on both sides of the assembly hole 340H than in the center.

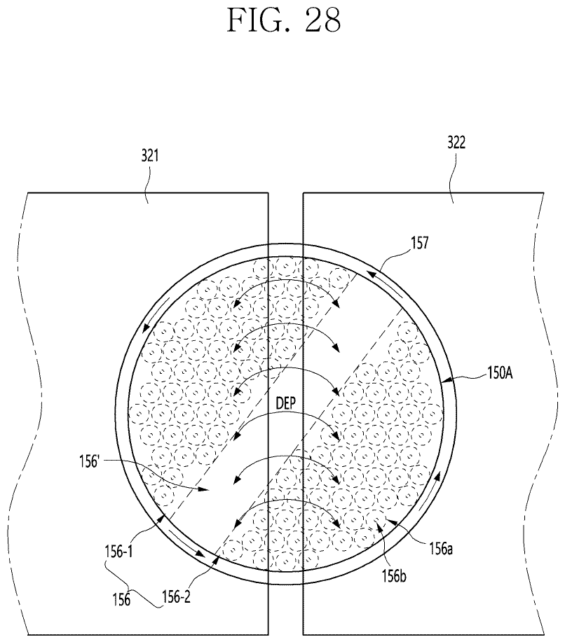

In this instance, as illustrated in FIG. 28, even when the circular semiconductor light-emitting element 150B is assembled into the assembly hole 340H of the backplane substrate 300A in a state of being rotated by a predetermined angle from its correct position, the second-first non-uniform region 156-1 and the second-second non-uniform region 156-2, which are positioned on both sides of the second uniform region 156′ in the first electrode 154, may be self-aligned to overlap with the first assembly wiring 321 and the second assembly wiring 322, respectively, so that the semiconductor light-emitting element 150B may be assembled in its correct position.

That is, a DEP force may be formed between the first assembly wiring 321 and the second assembly wiring 322, and a DEP force greater than that of the second uniform region 156′ may be formed in each of the second-first non-uniform region 156-1 and the second-second non-uniform region 156-2 positioned on both sides of the second uniform region 156′, so that the semiconductor light-emitting element 150B may be self-aligned so that the second-first non-uniform region 156-1 and the second-second non-uniform region 156-2 of the first electrode 154 of the semiconductor light-emitting element 150B may be aligned with, i.e., overlap with, the first assembly wiring 321 and the second assembly wiring 322. The second-first non-uniform region 156-1 and the second-second non-uniform region 156-2, which are positioned on both sides of the second uniform region 156′, may be aligned to the first assembly wiring 321 and the second assembly wiring 322, respectively, so that the semiconductor light-emitting element 150B may be aligned to the correct position. In this instance, when the semiconductor light-emitting element 150B is not assembled in the correct position in the assembly hole 340H, a separate alignment process for assembling it in the correct position does not need to be performed, and a problem caused by not being aligned in the correct position, i.e., electrical connection defect due to misalignment, can be prevented.

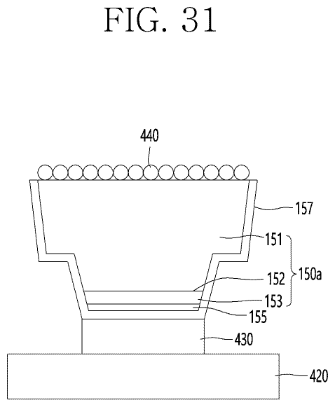

FIGS. 31 to 40 illustrate a method for manufacturing a semiconductor light-emitting element according to the second embodiment.

FIG. 31 is the same as FIG. 11. Therefore, as illustrated in FIG. 31, particles 440 may be applied on the surface of the light-emitting layer 150a exposed by removing the growth substrate 410 through the process illustrated in FIG. 9 and FIG. 10.

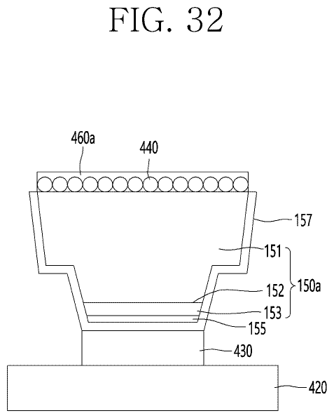

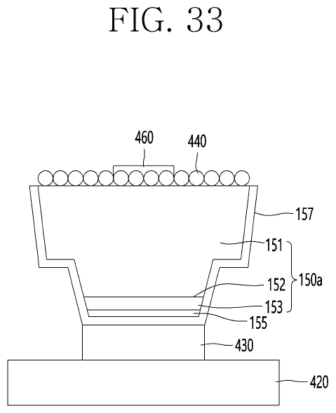

A photosensitive film 460a may be coated on the particles 440 (FIG. 32), and the photosensitive film 460a may be patterned to form a PR pattern 460 (FIG. 33). The PR pattern 460 may be formed long in both directions at the center of the light-emitting layer 150a.

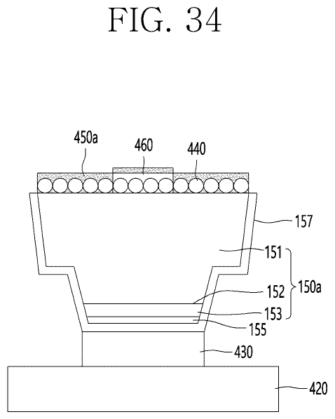

As illustrated in FIG. 34, a fixed film 450a may be formed on the particles 440. The fixed film 450a may be formed on the PR pattern 460. The fixed film 450a may comprise an inorganic material such as SiO2 or SiNx, but is not limited thereto. The fixed film 450a may be formed between the particles 440 and under the particles 440. The particles 440 may be firmly fixed on the light-emitting layer 150a through the fixed film 450a.

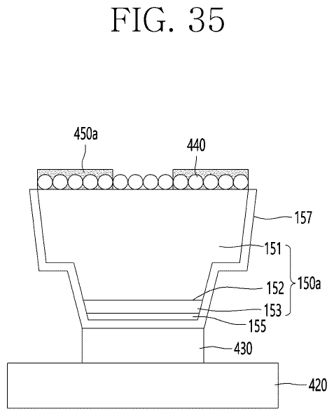

As illustrated in FIG. 35, the particles 440 fixed by the PR pattern 460 together with the PR pattern 460 may be removed, thereby exposing the center of the light-emitting layer 150a.

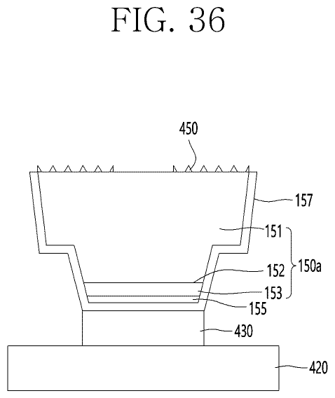

As illustrated in FIG. 36, the fixed film 450a positioned on the particles 440 may be removed, and the particles 440 may be also removed, thereby forming a pattern mask 450 on both sides of the light-emitting layer 150a. The pattern mask 450 may have a shape corresponding to the shape of the particles 440. The pattern mask 450 may have a structure in which patterns are formed between the particles 440 and no pattern is formed under the particles 440.

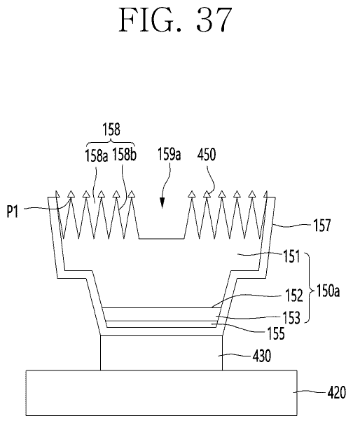

As illustrated in FIG. 37, an etching process may be performed using the pattern mask 450, so that the center of the light-emitting layer 150a may be etched to form a first uniform region 158′ having a first recess, and both sides of the light-emitting layer 150a may be etched through the regions between the patterns of the pattern mask 450 to form a first-first non-uniform region 158-1 and a first-second non-uniform region 158-2 each comprising a plurality of first negative patterns 158a and a plurality of first protrusions 158b.

The first conductivity type semiconductor layer 151 of the light-emitting layer 150a corresponding to the regions between the patterns of the pattern mask 450 may be removed, but the first conductivity type semiconductor layer 151 of the light-emitting layer 150a corresponding to the patterns of the pattern mask 450 may not be removed. While the etching process is continuously performed, the first conductivity type semiconductor layer 151 corresponding to the patterns of the pattern mask 450 may also be over-etched, so that the first peak P1 may be formed at the vertex of the first protrusion 158b. Meanwhile, the deepest bottom of the first negative pattern 158a may become increasingly difficult to etch, so that a furrow or valley may be formed.

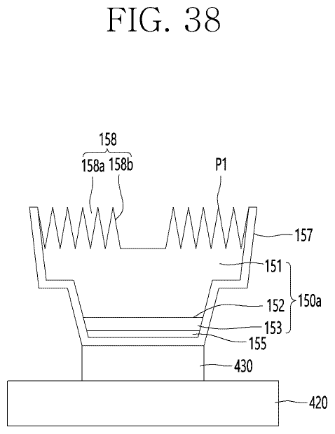

As illustrated in FIG. 38, the pattern mask 450 may be removed.

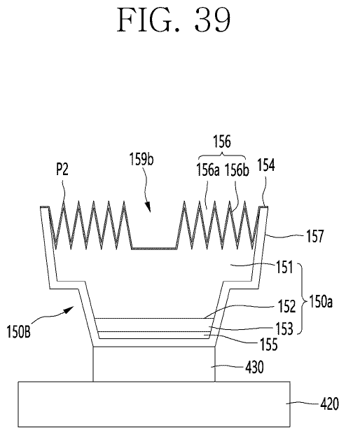

As illustrated in FIG. 39, the first electrode 154 may be formed on the first uniform region 158′, the first-first non-uniform region 158-1, and the first-second non-uniform region 158-2. In this instance, the first electrode 154 may comprise the second non-uniform region 156 and the second uniform region 156′. The second non-uniform region 156 may comprise the second-first non-uniform region 156-1 and the second-second non-uniform region 156-2. The second-first non-uniform region 156-1 may have a shape corresponding to the shape of the first-first non-uniform region 158-1. The second-second non-uniform region 156-2 may have a shape corresponding to the shape of the first-second non-uniform region 158-2. The second uniform region 156′ may have a shape corresponding to the shape of the first uniform region 158′. In this instance, the second-first non-uniform region 156-1 and the second-second non-uniform region 156-2 may each comprise a plurality of second negative patterns 156a and a plurality of second protrusions 156b.

As described above, a semiconductor light-emitting element 150B according to the second embodiment, which is composed of a light-emitting layer 150a, a passivation layer 157, a first electrode 154, and a second electrode 155, may be manufactured.

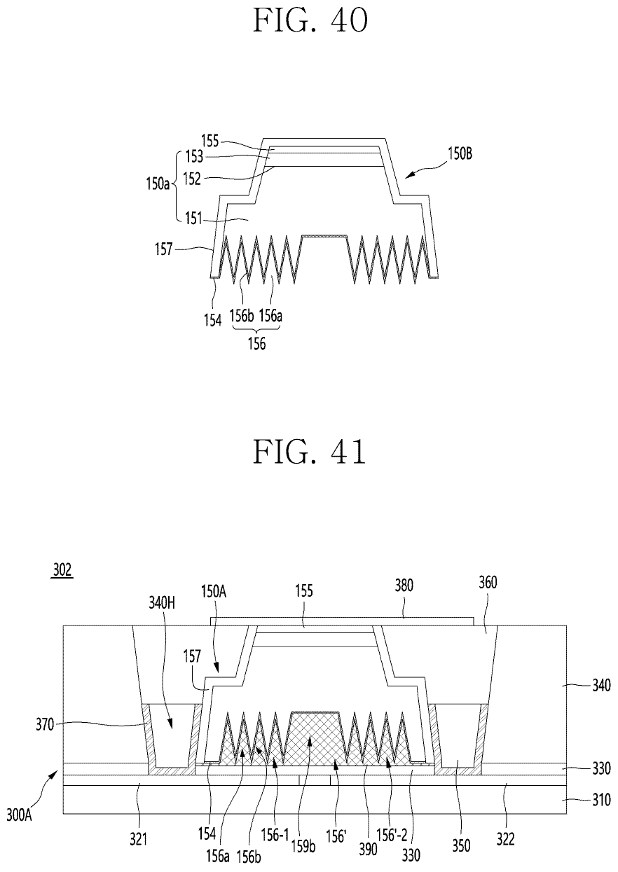

As illustrated in FIG. 40, the semiconductor light-emitting element 150B according to the second embodiment may be separated from the temporary substrate 420 by removing the sacrificial layer using an etchant.

FIG. 41 is a cross-sectional view illustrating a display device according to the second embodiment.

The embodiment is the same as the first embodiment (FIG. 18) except for the semiconductor light-emitting element 150B. In the second embodiment, components having the same shape, structure, and/or function as those of the first embodiment are given the same drawing reference numerals, and detailed descriptions thereof are omitted.

Referring to FIG. 41, the display device 302 according to the second embodiment may comprise a backplane substrate 300A, a semiconductor light-emitting element 150B, a fixing member 390, a connecting electrode 370, and an electrode wiring 380.

The semiconductor light-emitting element 150B may be the semiconductor light-emitting element 150B according to the second embodiment illustrated in FIG. 26.

Since a second recess 159b is formed in the center of the lower side of the semiconductor light-emitting element 150B, and a fixing member 390 is disposed in the second recess 159b, the contact area between the fixing member 390 and the semiconductor light-emitting element 150B can be significantly increased. Accordingly, the fixing property of the semiconductor light-emitting element 150B can be further strengthened by the fixing member 390, so that assembly defect can be prevented and the lighting yield can be improved.

### Third Embodiment

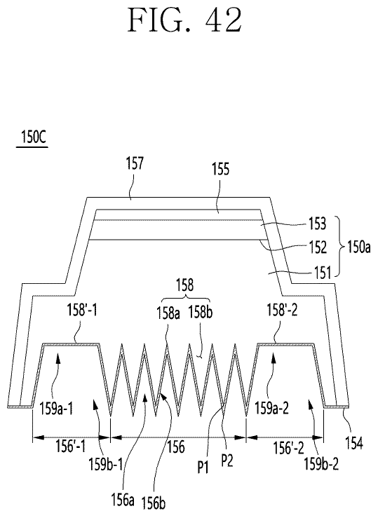

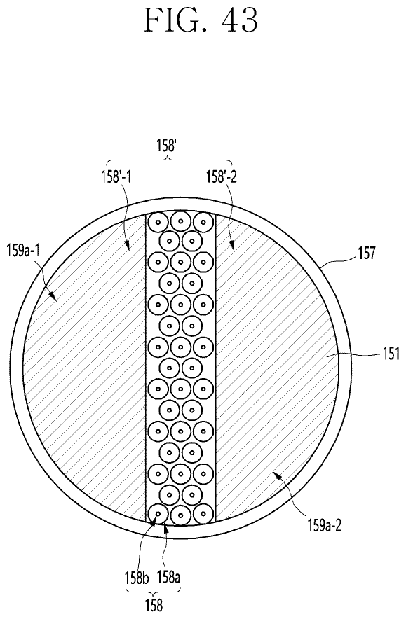

FIG. 42 is a cross-sectional view illustrating a semiconductor light-emitting element according to a third embodiment. FIG. 43 is a bottom view of the semiconductor light-emitting element according to the third embodiment with the first electrode removed.

The embodiment is the same as the second embodiment except for the arrangement positions of the second uniform region 156′ and the second non-uniform region 156 of the first electrode 154. In the third embodiment, components having the same shape, structure, and/or function as those of the second embodiment are given the same drawing reference numerals, and detailed descriptions thereof are omitted.

Referring to FIGS. 42 and 43, the semiconductor light-emitting element 150C according to the third embodiment may comprise a light-emitting layer 150a, a passivation layer 157, a first non-uniform region 158, a first uniform region 158′, a first electrode 154, and a second electrode 155.

The first non-uniform region 158 may be disposed long along both directions in the center of the light-emitting layer 150a. The first non-uniform region 158 may comprise a plurality of first negative patterns 158a and a plurality of first protrusions 158b.

The first uniform region 158′ may comprise the first-first uniform region and the first-second uniform region. The first-first uniform region and the first-second uniform region may be disposed on both sides of the light-emitting layer 150a. The first non-uniform region 158 may be positioned between the first-first uniform region and the first-second uniform region. The first-first uniform region may be positioned on one side of the first non-uniform region 158, and the first-second uniform region may be positioned on the other side of the first non-uniform region 158.

The first-first uniform region may have the first-first recess 159a-1, and the first-second uniform region may have the first-second recess 159a-2. The first-first recess 159a-1 and the first-second recess 159a-2 may have the same depth, but is not limited thereto.

The first electrode 154 may comprise a second uniform region 156′ and a second non-uniform region 156.

The second non-uniform region 156 may have a shape corresponding to the shape of the first non-uniform region 158. The second uniform region 156′ may have a shape corresponding to the shape of the first uniform region 158′. The second non-uniform region 156 may comprise a plurality of second negative patterns 156a and a plurality of second protrusions 156b.

The second uniform region 156′ may comprise a second-first uniform region 156′-1 and a second-second uniform region 156′-2. The second-first uniform region 156′-1 may have a shape corresponding to the shape of the first-first uniform region. The second-second uniform region 156′-2 may have a shape corresponding to the shape of the first-second uniform region. The second-first uniform region 156′-1 may have a second-first recess 159b-1, and the second-second uniform region 156′-2 may have a second-second recess 159b-2. The second-first recess 159b-1 and the second-second recess 159b-2 may have the same depth, but is not limited thereto.

Although not illustrated, the first uniform region 158′ and the second uniform region 156′ may not have the first recess and the second recess 159b, respectively. When the lower surface of the first conductivity type semiconductor layer 151 is not etched, the lower surface of the first conductivity type semiconductor layer 151 itself becomes the first uniform region 158′, and the second uniform region 156′ of the first electrode 154 may be formed on the first uniform region 158′. In this instance, the surface of the first uniform region 158′ may be positioned on the same horizontal line as the first peak P1 of the first protrusion 158b.

Meanwhile, the second non-uniform region 156 may be positioned between the second-first uniform region 156′-1 and the second-second uniform region 156′-2.

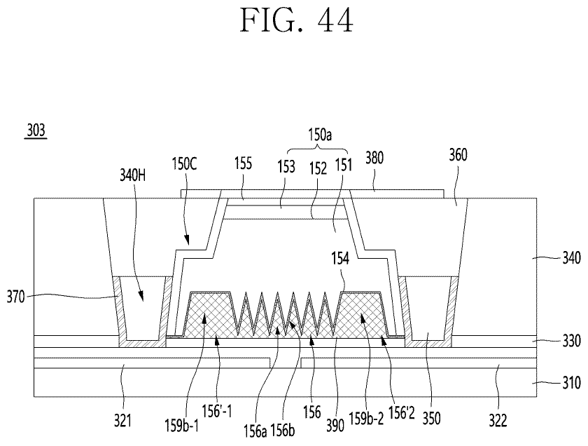

FIG. 44 is a cross-sectional view illustrating a display device according to the third embodiment.

The embodiment is the same as the first embodiment (FIG. 18) except for the semiconductor light-emitting element 150C. In the third embodiment, components having the same shape, structure, and/or function as those in the first embodiment are given the same drawing reference numerals, and detailed descriptions thereof are omitted.

Referring to FIG. 44, the display device 303 according to the third embodiment may comprise a backplane substrate 300A, a semiconductor light-emitting element 150C, a fixing member 390, a connecting electrode 370, and an electrode wiring 380.

The semiconductor light-emitting element 150C may be the semiconductor light-emitting element 150C according to the third embodiment illustrated in FIG. 42.

Since the second-first recess 159b-1 and the second-second recess 159b-2 are formed on both sides of the lower side of the semiconductor light-emitting element 150C, and the fixing member 390 is disposed in the second-first recess 159b-1 and the second-second recess 159b-2, the contact area between the fixing member 390 and the semiconductor light-emitting element 150C can be significantly increased. Accordingly, the fixing property of the semiconductor light-emitting element 150C can be further strengthened by the fixing member 390, so that assembly defect can be prevented and the lighting yield can be improved.

Meanwhile, the display device described above may be a display panel. That is, in the embodiment, the display device and the display panel may be understood to have the same meaning. In the embodiment, the display device in a practical sense may comprise a display panel and a controller (or processor) capable of controlling the display panel to display an image.

The above detailed description should not be construed as limiting in all respects and should be considered illustrative. The scope of the embodiment should be determined by reasonable interpretation of the appended claims, and all changes within the equivalent range of the embodiment are included in the scope of the embodiment.

### INDUSTRIAL APPLICABILITY

The embodiment may be adopted in the display field for displaying images or information. The embodiments may be adopted in the display field for displaying images or information using a semiconductor light-emitting element. The semiconductor light-emitting element may be a micro-level semiconductor light-emitting element or a nano-level semiconductor light-emitting element.

For example, the embodiment may be adopted in a TV, a signage, a mobile terminal such as a mobile phone or a smart phone, a computer display such as a laptop or a desktop, a head-up display (HUD) for an automobile, a backlight unit for display, a display for an extended reality (XR) such as AR, VR, and a mixed reality (MR), a light source, etc.

1. A semiconductor light-emitting element, comprising:
a light-emitting layer comprising a first emission region, a second emission region, and a third emission region between the first emission region and the second emission region;
a passivation layer surrounding the light-emitting layer;
a first-first non-uniform region under the first emission region of the light-emitting layer;
a first-second non-uniform region under the second emission region of the light-emitting layer;
a first uniform region under the third emission of the light-emitting layer;
a first electrode comprising a second-first non-uniform region, a second-second non-uniform region, and a second uniform region under the first-first non-uniform region, the first-second non-uniform region, and the first uniform region, respectively; and
a second electrode on the light-emitting layer,
wherein each of the first-first non-uniform region and the first-second non-uniform region comprises a plurality of first negative patterns and a plurality of first protrusions on the plurality of first negative patterns,
wherein each of the second-first non-uniform region and the second-second non-uniform region comprises a plurality of second negative patterns and a plurality of second protrusions on the plurality of second negative patterns,
wherein the plurality of second negative patterns have shapes corresponding to shapes of the plurality of first negative patterns, respectively, and
wherein the plurality of second protrusions have shapes corresponding to shapes of the plurality of first protrusions, respectively.

2. The semiconductor light-emitting element of claim 1, wherein the first protrusion has a first peak, and
wherein the second protrusion has a second peak having a shape corresponding to a shape of the first peak.

3. The semiconductor light-emitting element of claim 1, wherein the first negative pattern and the second negative pattern have ring shapes around the first protrusion and the second protrusion, respectively.

4. The semiconductor light-emitting element of claim 1, wherein a maximum diameter of the first protrusion or a maximum width of the first negative pattern is 100 nm or less.

5. The semiconductor light-emitting element of claim 1, wherein the light-emitting layer comprises:
a first conductivity type semiconductor layer;
an active layer on the first conductivity type semiconductor layer; and
a second conductivity type semiconductor layer on the active layer,
wherein the first conductivity type semiconductor layer has a thickness of 70% or more of a total thickness of the light-emitting layer.

6. The semiconductor light-emitting element of claim 5, wherein a height of the first protrusion is 20% to 70% of a thickness of the first conductivity type semiconductor layer.

7. The semiconductor light-emitting element of claim 6, wherein a thickness of the first electrode of 30% or less of the height of the first protrusion.

8. The semiconductor light-emitting element of claim 7, wherein the first electrode comprises a plurality of metal layers comprising at least an ohmic contact layer and a magnetic layer, and wherein each of the plurality of metal layers has a thickness of 50 nm or less.

9.-11. (canceled)

12. The semiconductor light-emitting element of claim 5, wherein the first uniform region, the first-first non-uniform region, and the first-second non-uniform region are parts of the first conductivity type semiconductor layer.

13. The semiconductor light-emitting element of claim 5, wherein the first uniform region has a first recess formed on a lower surface of the first conductivity type semiconductor layer, and the second uniform region has a second recess corresponding to the first recess.

14. The semiconductor light-emitting element of claim 13, wherein a surface of the first uniform region is positioned on a same horizontal line as the bottom of the first negative pattern.

15. A display device, comprising:
a backplane substrate;
the semiconductor light-emitting element of claim 15 on the backplane substrate;
a fixing member between the backplane substrate and the semiconductor light-emitting element;
a connecting electrode on a lateral part of the semiconductor light-emitting element; and
an electrode wiring on an upper side of the semiconductor light-emitting element,
wherein the connecting electrode is connected to at least one of a first assembly wiring or a second assembly wiring of the backplane substrate.

16. The display device of claim 15, wherein the fixing member is disposed in a second recess.

17. The display device of claim 15, wherein the fixing member is disposed in the plurality of second negative patterns of the first electrode.
